(19) United States
(12) Patent Application Publication
(10) Pub. No.: US 2026/0324172 A1
(43) Pub. Date: Oct. 15, 2026

(54) LIGHT-EMITTING MODULE

(71) Applicant: NICHIA CORPORATION, Anan-shi (JP)

(72) Inventor: Norimasa YOSHIDA, Tokushima-shi (JP)

(73) Assignee: NICHIA CORPORATION, Anan-shi (JP)

(21) Appl. No.: 19/640,028

(22) Filed: Apr. 6, 2026

(30) Foreign Application Priority Data
Apr. 10, 2025 (JP) 2025-065269

(51) Int. Cl. H10H 29/855; H10H 29/24; H10H 29/85

(52) U.S. Cl. CPC H10H 29/855; H10H 29/24; H10H 29/8506

(57) ABSTRACT

A light-emitting module includes: a light source including a plurality of light-emitting parts capable of individual operation or group operation, the plurality of light-emitting parts including at least one first light-emitting part and at least one second light-emitting part; and an array lens including a plurality of lens parts having positive refractive power, the plurality of lens parts being connected by one or more connecting portions. The array lens is disposed above the light source with a space therebetween. In a top view: the at least one first light-emitting part overlaps the connecting portion, and the at least one second light-emitting part is disposed below one of the lens parts and does not overlap the connecting portion.

### CROSS-REFERENCE TO RELATED APPLICATION

This application claims priority to Japanese Patent Application No. 2025-065269, filed on Apr. 10, 2025, the disclosure of which is hereby incorporated by reference in its entirety.

### TECHNICAL FIELD

The present disclosure relates to a light-emitting module.

### BACKGROUND

Light-emitting modules having semiconductor elements such as light emitting diodes (LEDs) have been widely used. As such a light-emitting module, an LED component has been disclosed which includes LED chips mounted in an array on a submount, and a collective optical lens having a plurality of convex optical features covering the LED chips (See, for example, Japanese Patent Publication No. 2013-179302).

### SUMMARY

Embodiments of the present disclosure are intended to provide a light-emitting module capable of light distribution control.

A light-emitting module according to an embodiment of the present disclosure includes at least one first light-emitting part and at least one second light-emitting part, and a light source having a plurality of light-emitting parts capable of individual operation or group operation, and an array lens including a plurality of lens parts having positive refractive power, wherein the plurality of lens parts are connected by one or more connecting portions, and the array lens is disposed above the light source with a space therebetween, and in a top view, the first light-emitting part overlaps the connecting portion, and the second light-emitting part is disposed below one of the lens parts and does not overlap the connecting portion.

According to the embodiments of the present disclosure, it is possible to provide a light-emitting module capable of light distribution control.

### BRIEF DESCRIPTION OF THE DRAWINGS

FIG. 1 is a schematic top view of a light-emitting module according to a first embodiment.

FIG. 2 is a schematic cross-sectional view taken along line II-II in FIG. 1.

FIG. 3 is a schematic cross-sectional view taken along line III-III in FIG. 1.

FIG. 4 is a schematic cross-sectional view taken along line IV-IV in FIG. 1.

FIG. 5 is a schematic top view of a light source of the light-emitting module according to the first embodiment.

FIG. 6 is a schematic cross-sectional view taken along line VI-VI in FIG. 5.

FIG. 7 is a schematic top view of a light-emitting module according to a second embodiment.

FIG. 8 is a schematic bottom view of an array lens of the light-emitting module according to the second embodiment.

FIG. 9 is a schematic cross-sectional view taken along line IX-IX in FIG. 7.

FIG. 10 is a first diagram showing an example of a relationship among an emission pattern, a light distribution, and an illuminance of a light source of the light-emitting module according to the second embodiment.

FIG. 11 is a second diagram showing an example of a relationship among an emission pattern, a light distribution, and an illuminance of a light source of the light-emitting module according to the second embodiment.

FIG. 12 is a diagram showing an example of a relationship between an emission pattern and an illuminance in an ultra-wide-angle light distribution and a telephoto light distribution for each of the light-emitting module according to the first embodiment and the light-emitting module according to a reference example.

FIG. 13 is a diagram showing an example of a relationship between a curvature radius of a light-incident concave portion of an array lens of the light-emitting module according to the second embodiment and a peripheral illuminance.

FIG. 14 is a diagram showing an example of a relationship between a curvature radius of a light-incident concave portion of an array lens of the light-emitting module according to the second embodiment and a central illuminance.

FIG. 15 is a diagram showing an example of a relationship between a curvature radius of a light-exiting concave portion of an array lens of the light-emitting module according to the second embodiment and a peripheral illuminance.

FIG. 16A is a diagram showing an illuminance distribution of irradiation light when only a third light-emitting part among a plurality of light-emitting parts is caused to emit light at a curvature radius of a light-exiting concave portion near XVIA in FIG. 15.

FIG. 16B is a diagram showing an illuminance distribution of irradiation light when only the third light-emitting part among the plurality of light-emitting parts is caused to emit light at a curvature radius of a light-exiting concave portion near XVIB in FIG. 15.

FIG. 16C is a diagram showing an illuminance distribution of irradiation light when only the third light-emitting part among the plurality of light-emitting parts is caused to emit light at a curvature radius of a light-exiting concave portion near XVIC in FIG. 15.

FIG. 17 is a diagram showing an example of a relationship between a curvature radius of a light-exiting concave portion of an array lens of the light-emitting module according to the second embodiment and a central illuminance.

FIG. 18A is a diagram showing an illuminance distribution of irradiation light when only second light-emitting parts at four corners among the plurality of light-emitting parts are caused to emit light at a curvature radius of a light-exiting concave portion near XVIIIA in FIG. 17.

FIG. 18B is a diagram showing an illuminance distribution of irradiation light when only the second light-emitting parts at the four corners among the plurality of light-emitting parts are caused to emit light at a curvature radius of a light-exiting concave portion near XVIIIB in FIG. 17.

FIG. 18C is a diagram showing an illuminance distribution of irradiation light when only the second light-emitting parts at the four corners among the plurality of light-emitting parts are caused to emit light at a curvature radius of a light-exiting concave portion near XVIIIC in FIG. 17.

FIG. 19 is a schematic top view of a light source of the light-emitting module according to a first modification.

FIG. 20 is a schematic top view of a light source of the light-emitting module according to a second modification.

FIG. 21A is a schematic top view showing a first example of a light source of the light-emitting module according to a third modification.

FIG. 21B is a schematic top view showing a second example of a light source of the light-emitting module according to the third modification.

FIG. 22 is a schematic top view of a light source of the light-emitting module according to a fourth modification.

FIG. 23 is a schematic top view showing a light source of the light-emitting module according to a fifth modification.

FIG. 24 is a schematic top view of an array lens of the light-emitting module according to a sixth modification.

FIG. 25 is a schematic top view of an array lens of the light-emitting module according to a seventh modification.

FIG. 26 is a schematic top view of an array lens of the light-emitting module according to an eighth modification.

FIG. 27A is a schematic cross-sectional view of the light-emitting module according to a ninth modification.

FIG. 27B is a schematic cross-sectional view of the light-emitting module according to the ninth modification.

FIG. 28A is a schematic top view of the light-emitting module according to a tenth modification.

FIG. 28B is a schematic cross-sectional view taken along line XXVIIIB-XXVIIIB in FIG. 28A.

FIG. 29 is a schematic cross-sectional view of the light-emitting module according to an eleventh modification.

FIG. 30A is a schematic top view of the light-emitting module according to a twelfth modification.

FIG. 30B is a schematic cross-sectional view taken along line XXXB-XXXB in FIG. 30A.

FIG. 30C is a schematic cross-sectional view taken along line XXXC-XXXC in FIG. 30A.

FIG. 31A is a schematic top view of the light-emitting module according to a thirteenth modification.

FIG. 31B is a schematic cross-sectional view taken along line XXXIB-XXXIB in FIG. 31A.

FIG. 31C is a schematic cross-sectional view taken along line XXXIC-XXXIC in FIG. 31A.

### DETAILED DESCRIPTION

Light-emitting modules according to embodiments of the present disclosure will be described in detail with reference to the drawings. However, the embodiments shown below are merely examples of light-emitting modules for embodying the technical concept of the present embodiment, and are not limited to the following. In addition, unless otherwise specified as being limited to a specific embodiment, the dimensions, materials, shapes, relative arrangements, and the like of the components described in the embodiments are not intended to limit the scope of the present disclosure to only those, but are merely illustrative examples. The sizes, positional relationships, and the like of the members shown in the drawings may be exaggerated for clarity of explanation. In the following description, the same names and reference numerals indicate the same or similar members, and detailed description thereof will be omitted as appropriate. In some cases, an end view showing only a cut surface may be used as a cross-sectional view.

In the drawings shown below, directions may be indicated by an X-axis, a Y-axis, and a Z-axis, wherein the X-axis, the Y-axis, and the Z-axis are mutually orthogonal directions. An X direction along the X-axis and a Y direction along the Y-axis indicate directions along an emission surface of a light-emitting part of the light-emitting module according to the embodiment. A Z direction along the Z-axis indicates a direction orthogonal to the emission surface. That is, the emission surface of the light-emitting part is parallel to an XY plane, and the Z-axis is orthogonal to the XY plane.

In the X direction, the direction in which the arrow points is denoted as the +X side, and the opposite side of the +X side is denoted as the −X side. In the Y direction, the direction in which the arrow points is denoted as the +Y side, and the opposite side of the +Y side is denoted as the −Y side. In the Z direction, the direction in which the arrow points is denoted as the +Z side, and the opposite side of the +Z side is denoted as the −Z side. In the embodiment, the light-emitting part of the light-emitting module emits light toward the +Z side as an example. However, these definitions do not limit the orientation of the light-emitting module during use, and the orientation of the light-emitting module is arbitrary.

In this specification, a surface of an object viewed from the +Z side is referred to as an “upper surface,” and a surface of the object viewed from the −Z side is referred to as a “lower surface.” The +Z side as viewed from the object may be referred to as “above,” and the −Z side as viewed from the object may be referred to as “below.” In the embodiments described below, “along” the X-axis, Y-axis, and Z-axis includes having an inclination within ±10° with respect to these axes. In the embodiments described below, “orthogonal” may include an error within ±10° with respect to 90°. In this specification, “along” may include an error within ±10° with respect to 0°. Further, terms such as “dispose” “cover,” or “on” are not limited to a case in which two objects are in direct contact with each other, but also include a case where one object is disposed/covered/on with respect to another object indirectly, for example, via another member.

In this specification or in the claims, when there are a plurality of certain elements and each is identified, “first,” “second,” and the like may be added in front of the component names to identify them. Such an identification may differ between the specification and the claims.

### FIRST EMBODIMENT

### Configuration Example of Light-Emitting Module of First Embodiment

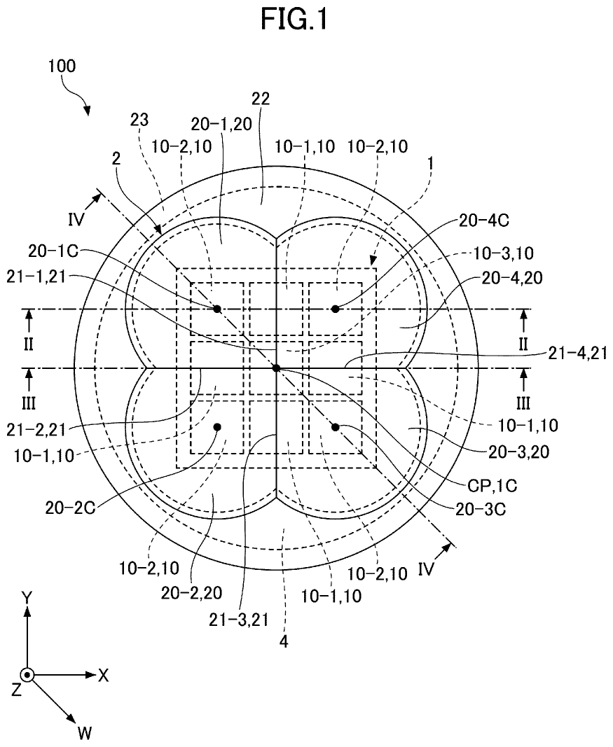

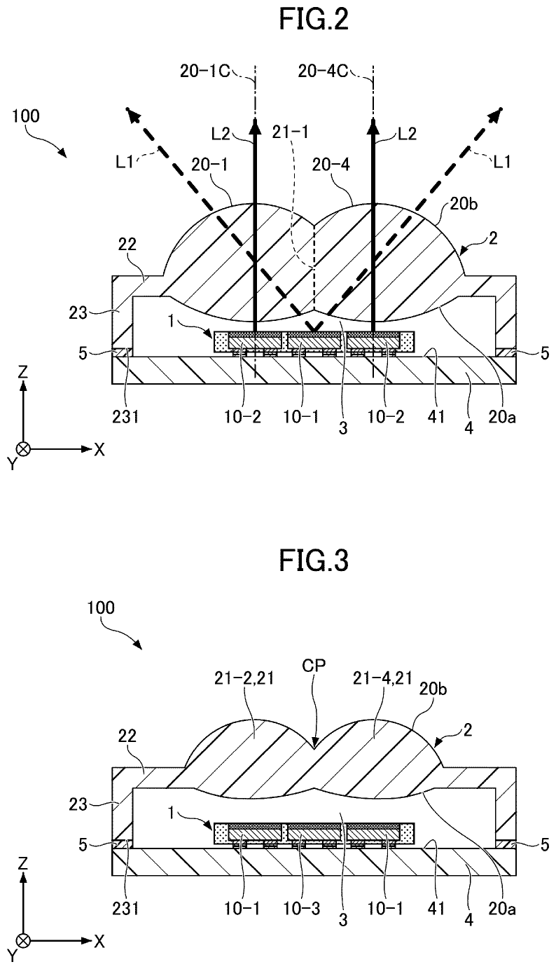

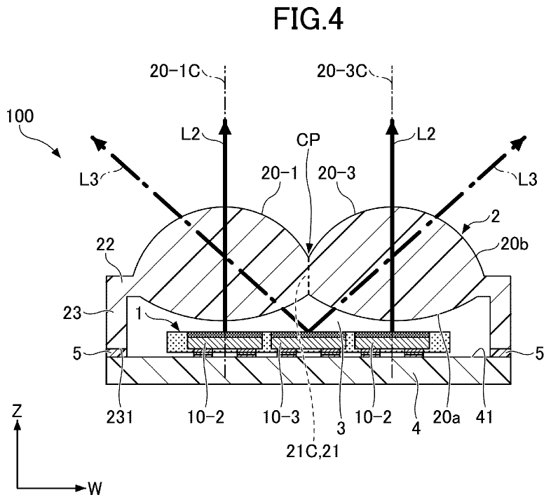

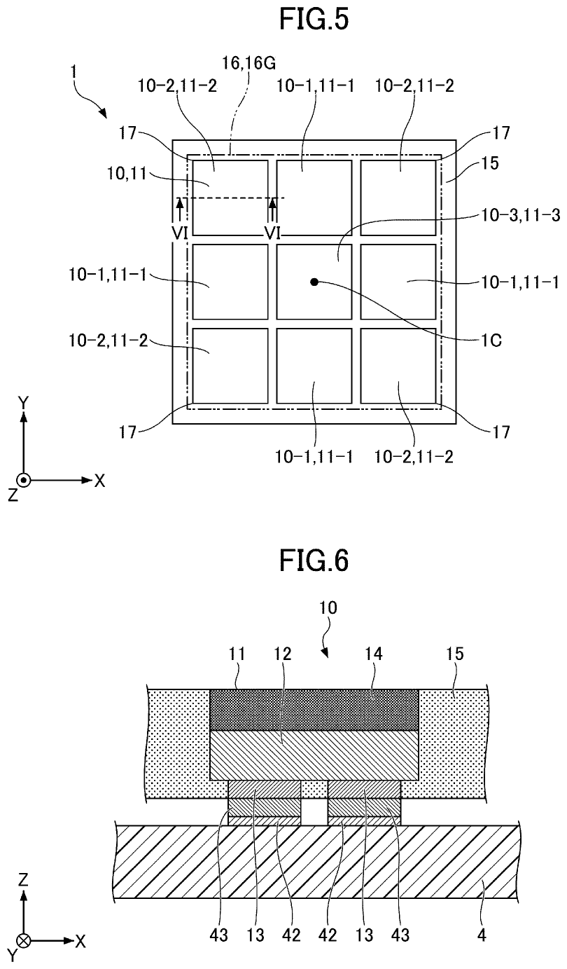

The configuration of a light-emitting module according to a first embodiment of the present disclosure will be described with reference to FIGS. 1 to 6. FIG. 1 is a schematic top view of a light-emitting module 100 according to the first embodiment. FIG. 2 is a schematic cross-sectional view taken along line II-II in FIG. 1. FIG. 3 is a schematic cross-sectional view taken along line III-III in FIG. 1. FIG. 4 is a schematic cross-sectional view taken along line IV-IV in FIG. 1. FIG. 5 is a schematic top view of a light source in the light-emitting module 100. FIG. 6 is a schematic cross-sectional view taken along line VI-VI in FIG. 5. In FIG. 1, part of the configuration corresponding to the cross-sectional view of FIG. 2 is omitted to avoid excessive complexity of the drawing.

The light-emitting module 100 is, as an example, a light-emitting module used as a light source device for a camera flash in an imaging device mounted in a smartphone. The imaging device includes, for example, a camera for capturing still images and a video camera for capturing moving images.

### (Overall Configuration)

As shown in FIGS. 1 and 2, the light-emitting module 100 includes a light source 1 including a plurality of light-emitting parts 10, and an array lens 2. The light source 1 includes at least one first light-emitting part 10-1 and at least one second light-emitting part 10-2. The plurality of light-emitting parts 10 can be driven individually or in groups. The array lens 2 is disposed above the light source 1 with a space 3 therebetween. The array lens 2 includes a plurality of lens parts 20 having positive refractive power. The plurality of lens parts 20 are connected by one or more connecting portions 21. In a top view, the first light-emitting part 10-1 overlaps the connecting portion 21. The second light-emitting part 10-2 is disposed below one of the lens parts 20 and, in a top view, does not overlap the connecting portion 21.

In FIG. 1, to indicate that the plurality of light-emitting parts 10 include the first light-emitting part 10-1 and the second light-emitting part 10-2, the reference numerals for the first light-emitting part 10-1 and the second light-emitting part 10-2 are shown together with the reference numeral for the plurality of light-emitting parts 10. The same notation may be used hereinafter for the same purpose.

“Refractive power” refers to the degree to which the traveling direction of incident light is bent. “Positive refractive power” is refractive power that bends parallel light in a converging direction when the light is incident. “Negative refractive power” is refractive power that bends parallel light in a diverging direction when the light is incident.

In the present embodiment, each of the plurality of lens parts 20 has an optical axis. The optical axes of the plurality of lens parts 20 are arranged at vertices of a rectangular shape in a top view. In the example shown in FIG. 1, the array lens 2 includes four lens parts 20. The four lens parts 20 include a lens part 20-1, a lens part 20-2, a lens part 20-3, and a lens part 20-4. The lens part 20-1 has an optical axis 20-1C. The lens part 20-2 has an optical axis 20-2C. The lens part 20-3 has an optical axis 20-3C. The lens part 20-4 has an optical axis 20-4C. The optical axes 20-1C, 20-2C, 20-3C, and 20-4C are arranged at vertices of a rectangular shape in a top view.

FIG. 2 shows a cross section of the light-emitting module 100 including the optical axis 20-1C of the lens part 20-1 and the optical axis 20-4C of the lens part 20-4. In FIG. 2, two principal rays L2 indicated by solid arrows represent principal rays passing through the lens part 20-1 and the lens part 20-4 among light emitted from the second light-emitting part 10-2. Two principal rays L1 indicated by dashed arrows represent principal rays passing through the lens part 20-1 and the lens part 20-4 among light emitted from the third light-emitting part 10-3.

The light-emitting module 100 can switch between irradiating light with a narrow-angle light distribution, light with a wide-angle light distribution, or light with an ultra-wide-angle light distribution by individual operation or group operation of nine light-emitting parts 10 including the first light-emitting part 10-1 and the second light-emitting part 10-2. The ultra-wide-angle light distribution has a larger full width at half maximum than the wide-angle light distribution. The wide-angle light distribution has a larger full width at half maximum than the narrow-angle light distribution.

When the light-emitting module 100 irradiates light with an ultra-wide-angle light distribution or a wide-angle light distribution, the emission intensity of the first light-emitting part 10-1 is made greater than or equal to the emission intensity of the second light-emitting part 10-2. When the light-emitting module 100 irradiates light with a narrow-angle light distribution, the emission intensity of the second light-emitting part 10-2 is made less than the emission intensity of the first light-emitting part 10-1.

In the light-emitting module 100, in a top view, the first light-emitting part 10-1 overlaps the connecting portion 21. Accordingly, when irradiating light with an ultra-wide-angle light distribution or a wide-angle light distribution, light from the first light-emitting part 10-1, which is located at a position not overlapping the optical axes 20-1C and 20-4C, passes through the lens part 20. When light from the first light-emitting part 10-1, which is located at a position not overlapping the optical axis, passes through the lens part 20, the light tends to spread more easily compared to a case where the first light-emitting part is located at a position overlapping the optical axis of the lens part, making it easier to obtain light with an ultra-wide-angle light distribution or a wide-angle light distribution. If a lens having only one lens part is referred to as lens E, in lens E, for example, to spread light, the light-emitting part is disposed at a position away from the optical axis of the lens part, and the curvature of the lens part is increased. When the light-emitting part is located away from the optical axis of the lens part, the utilization efficiency of light emitted from the light-emitting part decreases. In addition, if the curvature of the lens part increases, the thickness of the lens in the Z direction increases (this is referred to as lens E′). On the other hand, the array lens 2 of the present embodiment has a plurality of lens parts 20, and by disposing the first light-emitting part 10-1 at a position overlapping the connecting portion 21 between adjacent lens parts 20, the first light-emitting part 10-1 is positioned away from the optical axis of the lens part 20. Because light from the first light-emitting part 10-1 travels in a spreading direction (that is, toward the position of the optical axis of the lens part 20), the utilization efficiency of light is improved, and it is not necessary to increase the curvature of the lens part 20 to spread the light. Therefore, the array lens 2 of the present embodiment can efficiently emit light with a wide-angle light distribution compared to light emitted from lens E, while having the same curvature and the same lens thickness as the lens part of lens E. As a result, the light-emitting module 100 can emit light with an ultra-wide-angle light distribution or a wide-angle light distribution.

In addition, the second light-emitting part 10-2 is disposed below one of the lens parts 20 and does not overlap the connecting portion 21 in the top view. Accordingly, when irradiating light with a narrow-angle light distribution, light beams from the second light-emitting parts 10-2, which are respectively located at a position overlapping the optical axes 20-1C and 20-4C, pass through the lens part 20. When light from the second light-emitting part 10-2, which is located at a position overlapping the optical axis, passes through the lens part 20, the light tends to spread less compared to a case where the second light-emitting part is located at a position not overlapping the optical axis of the lens part, making it easier to obtain light with a narrow-angle light distribution. For example, most of the light from the second light-emitting part 10-2 can be controlled to enter the lens part 20 corresponding to the second light-emitting part 10-2, and thus light with a narrow-angle light distribution can be obtained while improving the utilization efficiency of light.

As described above, the light-emitting module 100 can control light distribution by individual operation or group operation of the plurality of light-emitting parts 10. In the first embodiment of the present disclosure, it is possible to provide the light-emitting module 100 capable of light distribution control.

In the example shown in FIGS. 1 to 4, the light-emitting module 100 includes a wiring substrate 4 and an adhesive member 5. The light source 1 is disposed on an upper surface 41 of the wiring substrate 4. The adhesive member 5 is disposed between a lower surface 231 of the array lens 2 and the upper surface 41 of the wiring substrate 4, and joins the array lens 2 and the wiring substrate 4.

In a top view, the light source 1 further includes a third light-emitting part 10-3 overlapping an intersection CP where the plurality of connecting portions 21 intersect. The plurality of light-emitting parts 10 include nine light-emitting parts 10 arranged in a matrix in a top view. The nine light-emitting parts 10 include four first light-emitting parts 10-1, four second light-emitting parts 10-2, and one third light-emitting part 10-3.

The array lens 2 includes four connecting portions 21. In a top view, the four connecting portions 21 include connecting portions 21-1, 21-2, 21-3, and 21-4, each extending linearly. The connecting portions 21-1 and 21-3 each extend linearly in the Y direction and are continuous with each other to form one straight line. The connecting portions 21-2 and 21-4 each extend linearly in the X direction and are continuous with each other to form one straight line. The straight line formed by the connecting portions 21-1 and 21-3 intersects with the straight line formed by the connecting portions 21-2 and 21-4 at the intersection CP. In a top view, the intersection CP overlaps a center 1C of the light source 1. The four first light-emitting parts 10-1 overlap the four connecting portions 21, respectively. The four second light-emitting parts 10-2 are respectively disposed below the four lens parts 20 and do not overlap any of the four connecting portions 21. In this specification, “corresponding” is not limited to being of the same type or different types, and may indicate that two things form a pair.

FIG. 3 shows a cross section of the light-emitting module 100 including the connecting portions 21-2 and 21-4. FIG. 4 shows a cross section of the light-emitting module 100 including the optical axis 20-1C of the lens part 20-1 and the optical axis 20-3C of the lens part 20-3. In FIG. 4, two principal rays L3 indicated by one-dot chain line arrows represent principal rays passing through the lens part 20-1 and the lens part 20-3 among light emitted from the third light-emitting part 10-3.

In the light-emitting module 100, because the light source 1 includes the third light-emitting part 10-3, light can be irradiated in symmetrical directions with respect to the intersection CP in a top view. This can improve the uniformity of illuminance in the irradiation light.

The four first light-emitting parts 10-1 overlap the four connecting portions 21, respectively, and the four second light-emitting parts 10-2 are respectively disposed below the four lens parts 20 and do not overlap any of the four connecting portions 21. Accordingly, when irradiating light with an ultra-wide-angle light distribution or a wide-angle light distribution, light from the first light-emitting part 10-1 tends to spread more easily, and when irradiating light with a narrow-angle light distribution, light from the second light-emitting part 10-2 tends to spread less. As a result, in the light-emitting module 100, the accuracy of light distribution control can be further improved.

The optical axes 20-1C, 20-2C, 20-3C, and 20-4C are arranged at vertices of a rectangular shape in a top view. Accordingly, when the light-emitting module 100 is used as a light source device for a camera flash, light can be irradiated to the four corners of a rectangular irradiation area corresponding to a camera angle of view, thereby improving the utilization efficiency of irradiation light in camera imaging. In this specification, “angle of view” refers to the angle indicating the width of the field of view that can be photographed or observed.

In the example shown in FIGS. 1 to 4, the shape of the light-emitting module 100 in a top view is substantially circular. However, the shape of the light-emitting module 100 in a top view may be substantially rectangular, substantially elliptical, or substantially polygonal.

The nine light-emitting parts 10 can control the light distribution of light emitted from the light-emitting module 100 by controlling the distribution of current supplied to each of the nine light-emitting parts 10.

The light-emitting module 100 can cause each of the nine light-emitting parts 10 to emit light individually, or to emit light in group(s), at a desired brightness. By controlling the emission of the plurality of light-emitting parts 10 in this manner, the contrast of irradiation light on an irradiation surface irradiated with light L from the light source 1 can be increased. In addition, the light-emitting module 100 can partially irradiate the irradiation surface by causing each of the nine light-emitting parts 10 to emit light individually or in groups. Here, “partial irradiation” refers to irradiating light to only a part of the irradiation surface.

Because partial irradiation irradiates light to only a part of the irradiation surface, it is preferable that the difference in illuminance of the irradiation light between a desired area to be irradiated and an area other than the desired area be large to make the light irradiating the desired area stand out. The light-emitting module 100 can make the light irradiating the desired area stand out by increasing the difference in illuminance of the irradiation light between the desired area and the area other than the desired area by causing each of the nine light-emitting parts 10 to emit light individually or in groups. In other words, the contrast of irradiation light on the irradiation surface can be increased.

When the light-emitting module 100 is used as a light source device for a camera flash of an imaging device, in a narrow-angle mode for irradiating light with a narrow-angle light distribution, the second light-emitting part 10-2 is mainly caused to emit light. In a wide-angle mode for irradiating light with an ultra-wide-angle light distribution or a wide-angle light distribution, the third light-emitting part 10-3 and the first light-emitting part 10-1 are mainly caused to emit light. Here, because light emitted from the second light-emitting part 10-2 can irradiate a central area of the irradiation area, in the wide-angle mode of the present embodiment, the second light-emitting part 10-2 is further caused to emit light to maintain the central illuminance of the irradiation light and adjust the uniformity of illuminance. The second light-emitting part 10-2 may not be caused to emit light. Because the light-emitting module 100 can switch irradiation light between the wide-angle mode and the narrow-angle mode, for example, light emitted from the light-emitting module 100 can be used to perform imaging with the imaging device according to an imaging mode such as close-up or telephoto. In this specification, “central illuminance” refers to the illuminance at the center of a rectangular irradiation area corresponding to a camera angle of view.

### (Light Source 1)

In the example shown in FIG. 5, the outer shape of the light source 1 in a top view is substantially rectangular. One light-emitting part 10 has one corresponding light-emitting surface 11, and each of the nine light-emitting parts 10 of the light source 1 has a substantially rectangular light-emitting surface 11 in a top view. The light-emitting surface 11 refers to a main light extraction surface of the light-emitting part 10. However, the shape of the light-emitting surface 11 in a top view may be substantially circular or substantially elliptical, or may be polygonal such as substantially triangular or substantially hexagonal.

A region including the light-emitting surface 11 corresponds to a light-emitting region 16. When there is one light-emitting surface 11, the one light-emitting surface 11 is the light-emitting region 16. When the light source 1 includes a plurality of light-emitting surfaces 11, the light-emitting region 16 is a region obtained by connecting outer edges of the light-emitting surfaces 11 located on the outer side in a top view. That is, in a top view, lines connecting the outer edges of the light-emitting surfaces 11 located on the outer side defines an outer perimeter 16G of the light-emitting region 16.

The shape of the outer edge 16G of the light-emitting region 16 is substantially rectangular in a top view and includes four corner portions 17. The light source 1 emits light from the light-emitting surface 11 included in each of the nine light-emitting parts 10 toward the position of the array lens 2. The number of light-emitting parts 10 included in the light source 1 is not limited to nine, and may be at least two including the first light-emitting part 10-1 and the second light-emitting part 10-2.

The plurality of light-emitting parts 10 are arranged vertically or laterally, or in a matrix in a top view. The plurality of light-emitting parts 10 are arranged along the X direction, or along both the X direction and the Y direction. In the example shown in FIG. 5, the nine light-emitting parts 10 are arranged along both the X direction and the Y direction. In a top view, the light-emitting parts 10 and the light-emitting surfaces 11 overlap, and therefore, in FIG. 5, the reference numerals for the light-emitting parts 10 and the reference numerals for the light-emitting surfaces 11 are shown together. Hereinafter, when two or more elements substantially coincide or overlap, the reference numerals may be shown together.

Each of the four first light-emitting parts 10-1 has a corresponding first light-emitting surface 11-1. Each of the four second light-emitting parts 10-2 has a corresponding second light-emitting surface 11-2. The one third light-emitting part 10-3 has one third light-emitting surface 11-3. The nine light-emitting surfaces 11 are disposed inside the array lens 2 in a top view, for example, inside the outer shape of the array lens 2.

### (Light-Emitting Part 10)

Because the nine light-emitting parts 10 can have the same configuration, in FIG. 6, the configuration of one light-emitting part 10 is described as a representative of the nine light-emitting parts 10. In the example shown in FIG. 6, the light-emitting part 10 has an upper surface serving as the light-emitting surface 11, and a mounting surface on the opposite side of the light-emitting surface 11, and is disposed on the +Z side surface of the wiring substrate 4. The light-emitting part 10 includes a light-emitting element 12, a wavelength conversion member 14 provided on the light-emitting element 12, and a covering member 15 covering the lateral surface(s) of the light-emitting element 12 and the lateral surface(s) of the wavelength conversion member 14 except for the upper surface of the wavelength conversion member 14. In other words, each of the lateral surface(s) of the light-emitting element 12 and the lateral surface(s) of the wavelength conversion member 14 is covered by the covering member 15. With this configuration, light leaking from the lateral surface(s) of the light-emitting element 12 and the lateral surface(s) of the wavelength conversion member 14 can be reduced, and light from the light source 1 can be irradiated to a desired area.

The plurality of light-emitting parts 10 included in the light source 1 have their covering members 15 continuous with each other between adjacent light-emitting parts 10. That is, the covering member 15 integrally holds the plurality of light-emitting elements 12 and the plurality of wavelength conversion members 14. With this configuration, compared to a case where the covering members 15 of adjacent light-emitting parts 10 are not continuous and each light-emitting part 10 is mounted independently, the plurality of light-emitting parts 10 can be mounted collectively, and the spacing between the light-emitting surfaces 11 can be reduced.

In the example shown in FIG. 6, the light-emitting surfaces 11 of adjacent light-emitting parts 10 among the nine light-emitting parts 10 are separated from each other by the covering member 15. However, the adjacent light-emitting surfaces 11 may be continuous. For example, one wavelength conversion member 14 may cover all of the plurality of light-emitting elements 12.

The light-emitting element 12 includes at least a pair of positive and negative electrodes 13 on a surface opposite to the light-emitting surface 11 (that is, the lower surface).

The light-emitting element 12 includes various semiconductors including a group III-V compound semiconductor and a group II-VI compound semiconductor, and the like. As the semiconductor, preferably, a nitride-based semiconductor such as In_{X}Al_{Y}Ga_{1-X-Y}N (0≤X, 0≤Y, X+Y≤1) is used, and any of InN, AlN, GaN, InGaN, AlGaN, InGaAlN, and the like can also be used. The light-emitting element 24 is an LED or a laser diode (LD), for example. A light emission peak wavelength of the light-emitting element 12 is preferably in a range of 400 nm to 530 nm, more preferably in a range of 420 nm to 490 nm, even more preferably in a range of 450 nm to 475 nm from the viewpoints of light emission efficiency, excitation of a wavelength conversion substance described below, and the like.

The wavelength conversion member 14 is, for example, a member having a rectangular shape in a top view. The wavelength conversion member 14 is provided so as to cover an upper surface of the light-emitting element 12. The wavelength conversion member 14 contains a wavelength conversion substance that converts a wavelength of at least part of light from the light-emitting element 12. The wavelength conversion member 14 can be formed using a light-transmissive resin material or an inorganic material such as ceramics or glass. As the resin material, a thermosetting resin, such as a silicone resin, a silicone modified resin, an epoxy resin, an epoxy modified resin, or a phenol resin, can be used. Particularly, a silicone resin or a modified resin thereof with high light resistance and heat resistance is used. The term “light-transmissive” here preferably refers to transmission of 60% or more of the light from the light-emitting element 12. In addition, the wavelength conversion member 14 may use a thermoplastic resin, such as a polycarbonate resin, an acrylic resin, a methyl pentene resin, or a polynorbornene resin. The wavelength conversion member 14 may be, for example, a member containing a wavelength conversion substance in a resin material, ceramics, glass, or the like, and a sintered body of the wavelength conversion substance. In addition, the wavelength conversion member 14 may also be a multilayer member in which a resin layer containing the wavelength conversion substance or the light diffusion substance is disposed on a ±Z side surface of a molded body of resin, ceramics, glass, or the like.

As the wavelength conversion substance contained in the wavelength conversion member 14, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used. The wavelength conversion substance described above is in the form of particles. Further, one of these types of wavelength conversion substance can be used alone, or two or more of these types of wavelength conversion substance can be used in combination.

In the present embodiment, the light source 1 uses a blue LED as the light-emitting element 12, and the wavelength conversion member 14 contains a wavelength conversion material that converts light emitted from the light-emitting element 12 into yellow light to emit white light. The wavelength or chromaticity of light emitted from the light source 1 may be appropriately selected according to the intended use of the light-emitting module 100. The wavelength conversion member 14 contains a light diffusing material in the above resin. Examples of the light diffusing material include titanium oxide, barium titanate, aluminum oxide, and silicon oxide. The wavelength conversion member 14 may not contain a light diffusing material.

The covering member 15 is a member that covers the lateral surfaces of the light-emitting element 12 and the wavelength conversion member 14. The covering member 15 covers the lateral surfaces of the light-emitting element 12 and the wavelength conversion member 14 directly or indirectly. In FIG. 6, the upper surface of the wavelength conversion member 14 is exposed from the covering member 15 and serves as the light-emitting surface 11 of the light-emitting part 10. The covering member 15 is formed of a material having high light reflectance to improve light extraction efficiency. In the present embodiment, the covering member 15 is formed of a resin material containing a light-reflective substance such as white pigment. The covering member 15 may also be a light-reflective member formed of an inorganic material containing boron nitride or alkali metal silicate. In this case, it may further contain titanium oxide or zirconium oxide.

The covering member 15 integrally holds the nine wavelength conversion members 14 and the nine light-emitting elements 12. From another perspective, the plurality of light-emitting parts 10 are connected to each other by the covering member 15. By connecting the plurality of light-emitting parts 10 with the covering member 15, the manufacturing efficiency of the light-emitting module 100 can be improved. In addition, by connecting the nine light-emitting parts 10 with the covering member 15, the area of the light-emitting region 16 of the light source 1 in a top view can be made smaller than in a case where the covering members of the nine light-emitting parts are separated from each other. This can allow the array lens 2 disposed above the light source 1 to be made smaller. Furthermore, by integrally holding the nine light-emitting elements 12 and the nine wavelength conversion members 14 with the covering member 15, mounting of the light source 1 becomes easier.

Examples of the light diffusion substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. One of these types of substance is preferably used alone, or a combination of two or more of these types of substance is preferably used. For the resin material, a resin material containing a thermosetting resin, such as an epoxy resin, an epoxy modified resin, a silicone resin, a silicone modified resin, or a phenol resin, as a main component is preferably used as a base material. The covering member 15 may be constituted by a member having transmissivity or absorption for visible light as necessary. The member having the light absorption contains, for example, carbon black. Light absorption with respect to visible light means that the reflectance of the irradiated light is less than 20%.

The light-emitting part 10 is electrically connected to wiring 42 provided in the wiring substrate 4. The wiring substrate 4 has wiring 42 on its surface. The wiring substrate 4 may have wiring 42 inside. The light-emitting part 10 and the wiring substrate 4 are electrically connected by connecting the wiring 42 of the wiring substrate 4 and at least a pair of positive and negative electrodes 13 of the light-emitting element 12 via a conductive member 43. The configuration and size of the wiring 42 of the wiring substrate 4 are set according to the configuration and size of the electrodes 13 of the light-emitting element 12.

The wiring substrate 4 is a substantially circular plate-like member in a top view. The wiring substrate 4 is a substrate including wiring capable of mounting the light source 1 or electronic components. The shape of the wiring substrate 4 in a top view may be substantially rectangular, substantially elliptical, or substantially polygonal.

It is preferable that the wiring substrate 4 use an insulating material as a base material, and it is preferable to use a material that is difficult to transmit light emitted from the light-emitting part 10 or all light entering the inside of the light-emitting module 100 from the outside of the light-emitting module 100. It is also preferable that the wiring substrate 4 use a material having a certain strength. Specifically, the wiring substrate 4 can be formed of ceramics such as alumina, aluminum nitride, mullite, or silicon nitride, or resins such as phenol resin, epoxy resin, polyimide resin, BT resin (bismaleimide triazine resin), polyphthalamide, or polyester resin as the base material.

The wiring 42 can be formed of at least one of copper, iron, nickel, tungsten, chromium, aluminum, silver, gold, titanium, palladium, rhodium, or alloys thereof. In addition, from the viewpoint of at least one of wettability of the conductive member 43 and light reflectivity of the wiring 42, a layer of silver, platinum, aluminum, rhodium, gold, or alloys thereof may be provided on the surface layer of the wiring 42.

### (Array Lens 2)

In the example shown in FIG. 1, the array lens 2 includes a support portion 22 disposed outward of the four lens parts 20, and a leg portion 23 disposed outward of the support portion 22, in a top view. The leg portion 23 disposed outward of the support portion 22 in a top view is continuously connected to the support portion 22, and supports the four lens parts 20 and the support portion 22. The four lens parts 20, the support portion 22, and the leg portion 23 are integrally formed.

The shape of the array lens 2 in a top view is substantially circular. However, the shape of the array lens 2 in a top view may be substantially rectangular, substantially elliptical, or substantially polygonal. The shape of the array lens 2 in a top view is rotationally symmetric. Considering that the imaging range of a general imaging device is substantially rectangular, the shape of the array lens 2 in a top view may be four-fold rotationally symmetric or two-fold rotationally symmetric. The shape and thickness in the Z direction of the lens parts 20 of the array lens 2 can be changed as appropriate.

In the present embodiment, in a top view, the outer edge shape of the structure composed of the plurality of lens parts 20 is an annular shape in which a plurality of arcs are connected. In the example shown in FIG. 1, the outer edge shape of the structure composed of the four lens parts 20 is an annular shape in which four arcs are connected. The annular shape of the structure composed of the plurality of lens parts 20 is not limited to a shape in which a plurality of arcs are connected. In this specification, “annular shape” refers to a shape having a continuous outer circumference, and the outer edge shape of the structure composed of the plurality of lens parts 20 includes a perfect circle, an elliptical shape, or a shape having other curves.

The four lens parts 20 are arranged in a 2×2 matrix in a top view, and are connected so that adjacent lens parts 20 in each of the X direction and the Y direction are connected by connecting portions 21. Specifically, the lens part 20-1 and the lens part 20-4 are connected in the X direction by the connecting portion 21-1. The lens part 20-1 and the lens part 20-2 are connected in the Y direction by the connecting portion 21-2. The lens part 20-2 and the lens part 20-3 are connected in the X direction by the connecting portion 21-3. The lens part 20-3 and the lens part 20-4 are connected in the Y direction by the connecting portion 21-4.

The support portion 22 is an annular portion provided outside the four lens parts 20 in a top view. The term “annular” includes an annular shape in a top view whose outer edge shape is substantially circular, substantially semicircular, substantially sector-shaped, substantially elliptical, substantially semi-elliptical, etc., including straight and arc-shaped lines, or a polygonal annular shape such as substantially square or substantially polygonal. In the example shown in FIG. 1, the outer edge shape of the support portion 22 in a top view is substantially circular.

The leg portion 23 is provided outside the support portion 22 in a top view so as to extend toward the −Z side (hereinafter sometimes referred to as “downward”). The leg portion 23 supports the four lens parts 20 and the support portion 22 such that the four lens parts 20 are disposed above the light source 1 and, in a top view, the support portion 22 is disposed outside the four lens parts 20. The array lens 2 may have at least one of the support portion 22 and the leg portion 23 as long as it has the lens parts 20, and may not have both the support portion 22 and the leg portion 23.

In the examples shown in FIGS. 2 to 4, each of the four lens parts 20 has a light-incident surface 20a into which light from the light source 1 enters, and a light-exiting surface 20b from which light exits from the lens part 20. The light-incident surface 20a is convex toward the direction in which the light source 1 is located (−Z side). The light-exiting surface 20b is convex toward the direction opposite to the direction in which the light source 1 is located (+Z side). That is, the array lens 2 includes a light-incident surface 2a that is a surface closer to the light source 1, and a light-exiting surface 2b located on the opposite side of the light-incident surface 2a. The lens part 20 has both the light-incident surface 20a and the light-exiting surface 20b as convex surfaces. In the present embodiment, the connecting portion 21 connecting the plurality of lens parts 20 is a boundary between adjacent lens parts 20, and in a cross section of the array lens 2 including the light-incident surface 2a and the light-exiting surface 2b, it refers to a portion including a surface parallel to the Z-axis from the light-incident surface 2a to the light-exiting surface 2b. That is, in the example shown in FIG. 2, the boundary between the lens part 20-1 and the lens part 20-4 is the connecting portion 21-1. In the example shown in FIG. 3, the cross section of the array lens 2 including the light-incident surface 2a and the light-exiting surface 2b is the connecting portions 21-2 and 21-4. In the example shown in FIG. 4, the boundary between the lens part 20-1 and the lens part 20-3 is the connecting portion 21C. The connecting portion 21C overlaps the intersection CP in a top view. In the present embodiment, the curvature radius of the light-incident surface 20a is greater than the curvature radius of the light-exiting surface 20b. This can allow light emitted from the light source 1 to efficiently enter the light-incident surface 20a. However, the curvature radius of the light-incident surface 20a may be less than or equal to the curvature radius of the light-exiting surface 20b. Each of the four lens parts 20 constitutes a biconvex single lens with the light-incident surface 20a and the light-exiting surface 20b. The array lens 2 includes a biconvex single-lens array composed of four biconvex single lenses. However, as long as the lens part 20 has positive refractive power, it is not limited to a biconvex single lens, and at least one of the light-incident surface 20a and the light-exiting surface 20b may be convex. The lens part 20 may also be a plano-convex single lens, a Fresnel lens, a compound lens composed of a plurality of lenses, a meniscus single lens, an aspherical lens, a cylindrical lens, or other shapes.

The array lens 2 can be configured to include at least one of a resin material such as polycarbonate resin, acrylic resin, silicone resin, or epoxy resin, or a glass material, which has light transmissivity with respect to light emitted from the light source 1. In the present embodiment, the lens parts 20, the support portion 22, and the leg portion 23 each include the same material and are connected to each other as an integral member. In the array lens 2, light transmissivity preferably means the property of transmitting 60% or more of the light from the light source 1. The size of the curvature radii of the light-incident surface 20a and the light-exiting surface 20b, the relationship between the curvature radii, and the thickness of the lens in the Z direction can be changed as appropriate.

### SECOND EMBODIMENT

Next, a light-emitting module according to a second embodiment of the present disclosure will be described. The same names and reference numerals as those already described in the embodiment indicate the same or similar members or configurations, and detailed description thereof will be omitted as appropriate. This also applies to the modified examples described below.

### Configuration of Light-Emitting Module of Second Embodiment

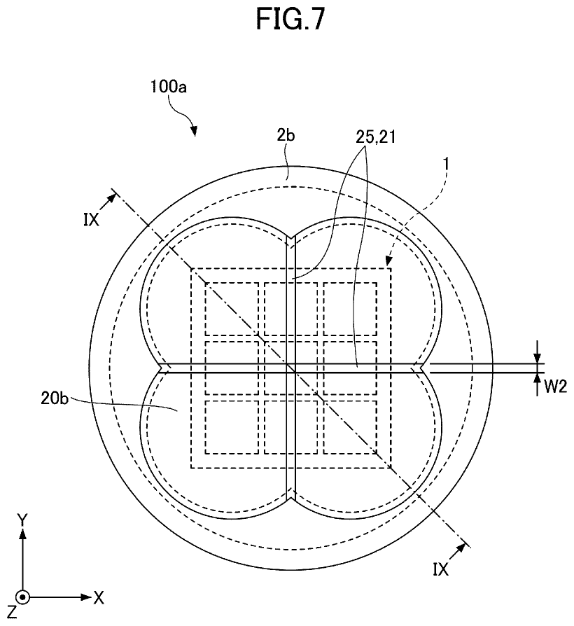

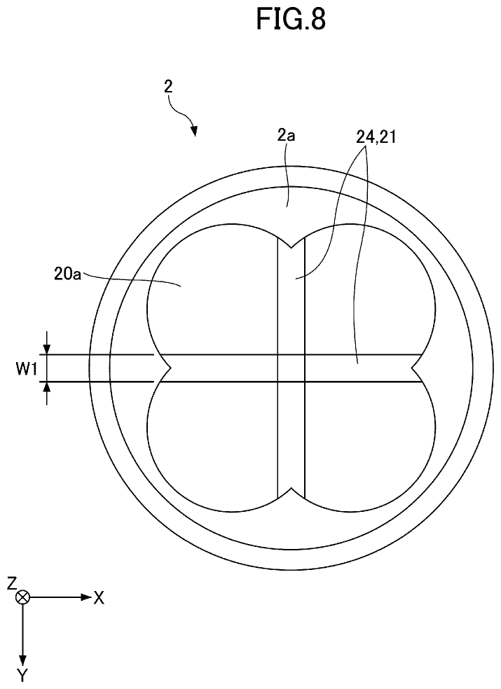

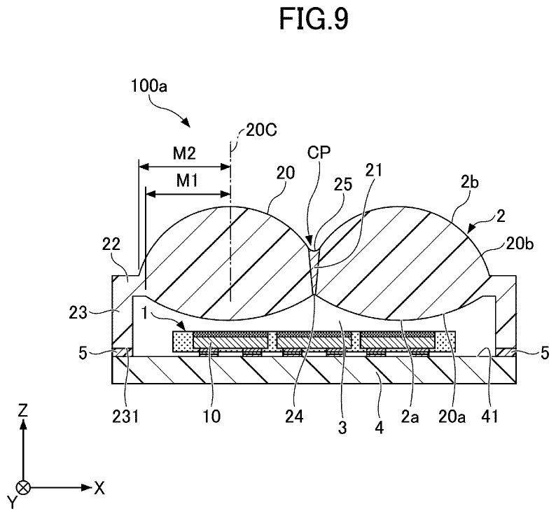

The configuration of a light-emitting module according to the second embodiment will be described with reference to FIGS. 7 to 9. FIG. 7 is a schematic top view of a light-emitting module 100a according to the second embodiment. FIG. 8 is a schematic bottom view of the array lens 2 of the light-emitting module 100a. FIG. 9 is a schematic cross-sectional view taken along line IX-IX in FIG. 7.

In the light-emitting module 100a according to the second embodiment, the array lens 2 includes a light-incident surface 2a that is a surface closer to the light source 1, and a light-exiting surface 2b located on the opposite side of the light-incident surface 2a. The lens part 20 has both the light-incident surface 20a and the light-exiting surface 20b as convex surfaces. The connecting portion 21 has a light-incident concave portion 24 on the light-incident surface 2a of the array lens 2, and a light-exiting concave portion 25 on the light-exiting surface 2b. The light-emitting module 100a according to the second embodiment differs from the light-emitting module 100 according to the first embodiment in that the connecting portion 21 has the light-incident concave portion 24 on the light-incident surface 2a and the light-exiting concave portion 25 on the light-exiting surface 2b.

In the example shown in FIG. 7, the light-exiting concave portion 25 is provided in the connecting portion 21 and extends in each of the X direction and the Y direction. The connecting portion 21 having the light-exiting concave portion 25 has continuous curvature. This can allow the light-exiting surface 20b of adjacent lens parts 20 and the connecting portion 21 (in other words, the light-exiting concave portion 25) to have a continuous curved surface and be smoothly linked. The maximum width w2 of the light-exiting concave portion 25 in a direction orthogonal to the direction in which the connecting portion 21 extends is 0.001 mm or more and 0.5 mm or less. In FIG. 7, the reference numerals for the light-exiting concave portion 25 and the connecting portion 21 are shown together to indicate that the light-exiting concave portion 25 is provided in the connecting portion 21. The same notation may be applied hereinafter for the same purpose.

In the example shown in FIG. 8, the light-incident concave portion 24 is provided in the connecting portion 21 and extends in each of the X direction and the Y direction. The connecting portion 21 having the light-incident concave portion 24 has continuous curvature. This can allow the light-incident surface 20a of adjacent lens parts 20 and the connecting portion 21 (in other words, the light-incident concave portion 24) to have a continuous curved surface and be smoothly connected. The maximum width w1 of the light-incident concave portion 24 in a direction orthogonal to the direction in which the connecting portion 21 extends is 0.001 mm or more and 0.5 mm or less.

In the examples shown in FIGS. 7 and 8, the maximum width w1 of the light-incident concave portion 24 is wider than the maximum width w2 of the light-exiting concave portion 25, and the lengths of the light-incident concave portion 24 and the light-exiting concave portion 25 in each of the X direction and the Y direction are equal. Therefore, in a top view, the area of the light-incident concave portion 24 is larger than the area of the light-exiting concave portion 25. In a top view, the area of the light-incident concave portion 24 may be equal to or smaller than the area of the light-exiting concave portion 25.

In FIG. 9, the maximum length M1 on the light-incident surface 2a side is the maximum length from the optical axis 20C of one lens part 20 to the outer edge of the light-incident surface 2a of this lens part 20. The maximum length M2 on the light-exiting surface 2b side is the maximum length from the optical axis 20C of one lens part 20 to the outer edge of the light-exiting surface 2b of the lens part 20.

In the light-emitting module 100a, the lens part 20 having both the light-incident surface 20a and the light-exiting surface 20b as convex surfaces can converge light from the light-emitting part 10, thereby improving the utilization efficiency of irradiation light. In addition, because the connecting portion 21 is provided with the light-incident concave portion 24, the light-incident surface 2a of the array lens 2 has a smooth curved surface at the connecting portion 21. Because the connecting portion 21 is provided with the light-exiting concave portion 25, the light-exiting surface 2b of the array lens 2 has a smooth curved surface at the connecting portion 21. Therefore, compared to a case where the light-incident concave portion 24 and the light-exiting concave portion 25 are not provided, it is possible to reduce abrupt changes in curvature at the connecting portion 21. This can reduce unintended diffusion or reflection-induced light loss at the connecting portion 21 for light that is emitted from the light source 1 and passes through the connecting portion 21, thereby increasing the utilization efficiency of light in the light-emitting module 100a. Specifically, the light-incident concave portion 24 can improve the utilization efficiency of light entering the array lens 2 when the first light-emitting part 10-1 and the third light-emitting part 10-3, which are disposed at positions overlapping the connecting portion 21 in a top view, are caused to emit light. The light-exiting concave portion 25 can reduce loss due to total internal reflection of light emitted from the first light-emitting part 10-1 and the third light-emitting part 10-3 and emitted from the array lens 2. Providing the light-incident concave portion 24 in the array lens 2 reduces the area of the light-incident surface 20a of the lens part 20 (that is, the area for controlling light of the lens part 20). However, because the second light-emitting part 10-2 in the present embodiment is located away from the light-incident concave portion 24, light emitted from the second light-emitting part 10-2 is less affected by the light-incident concave portion 24 than light emitted from the first light-emitting part 10-1 and the third light-emitting part 10-3. Therefore, in the narrow-angle mode, the light-emitting module 100a can maintain the central illuminance of light emitted from the second light-emitting part 10-2.

In the light-emitting module 100a, because the maximum width w1 of the light-incident concave portion 24 and the maximum width w2 of the light-exiting concave portion 25 are each 0.001 mm or more and 0.5 mm or less, diffusion or reflection at the light-incident concave portion 24 can be reduced, and the illuminance of light extracted from the array lens 2 can be increased. In addition, because the area of the light-incident concave portion 24 in a top view is larger than the area of the light-exiting concave portion 25, it is possible to brighten light extracted from the array lens 2 in the ultra-wide-angle light distribution while reducing the effect on brightness of light extracted from the array lens 2 in the narrow-angle light distribution.

The light-incident concave portion 24 and the light-exiting concave portion 25 can be simultaneously formed by a mold during molding of the array lens 2. The positions and numbers of the light-incident concave portion 24 and the light-exiting concave portion 25 in the connecting portion 21 can be changed as appropriate. The light-incident concave portion 24 and the light-exiting concave portion 25 can also be formed by applying resin to the connecting portion 21 between the lens parts 20 after molding the array lens 2. In this case, resin tends to adhere to deep portions of the groove in the connecting portion 21 (for example, the intersection CP), and the sizes of the light-incident concave portion 24 and/or the light-exiting concave portion 25 vary depending on the location.

The lens part 20 may have one of the light-incident surface 20a or the light-exiting surface 20b as a convex surface, and the one of the light-incident concave portion 24 or the light-exiting concave portion 25 may have the connection portion 21. That is, the lens part 20 may have the light-incident surface 20a as a convex surface, and the connecting portion 21 may have the light-incident concave portion 24 on the light-incident surface 2a. The lens part 20 may have the light-exiting surface 20b as a convex surface, and the connecting portion 21 may have the light-exiting concave portion 25 on the light-exiting surface 2b. Even when the light-incident surface 20a of the lens part 20 is convex, the connecting portion 21 has the light-incident concave portion 24 on the light-incident surface 2a, and does not have the light-exiting concave portion 25 on the light-exiting surface 2b, the similar effects as described above can be obtained. Similarly, even when the light-exiting surface 20b of the lens part 20 is convex, the connecting portion 21 has the light-exiting concave portion 25 on the light-exiting surface 2b, and does not have the light-incident concave portion 24 on the light-incident surface 2a, the similar effects as described above can be obtained.

### Simulation Results of Relationship Among Emission Pattern, Light Distribution, and Illuminance of Light Source 1

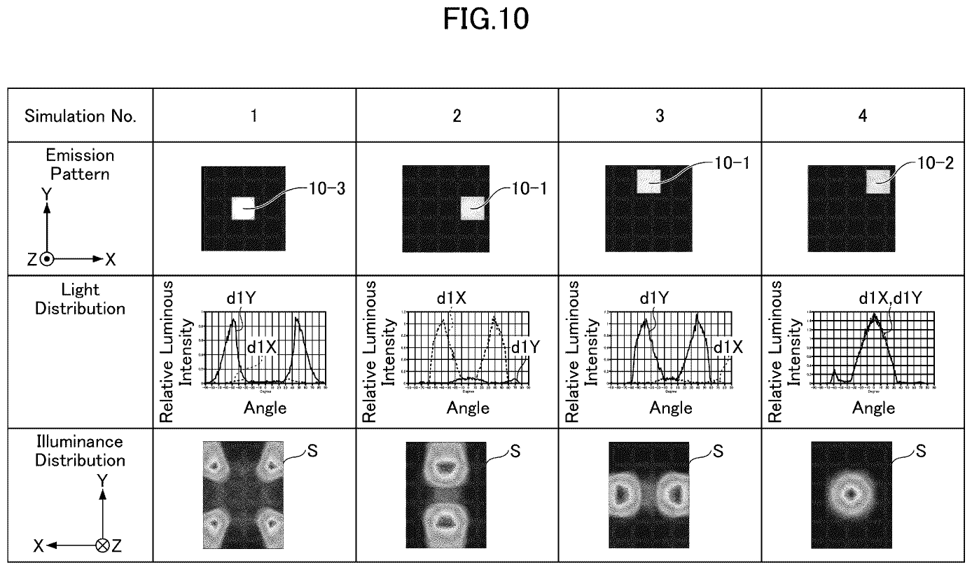

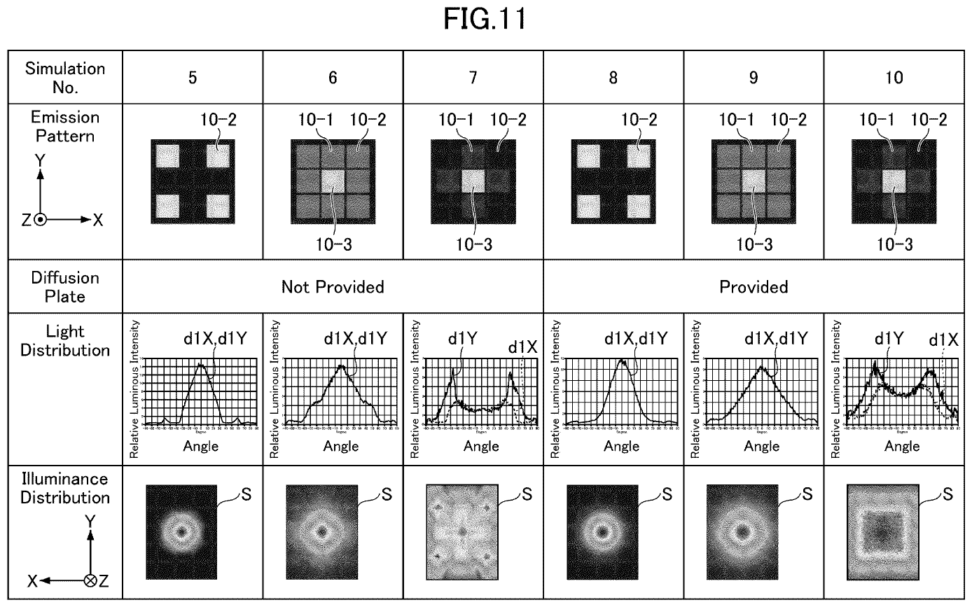

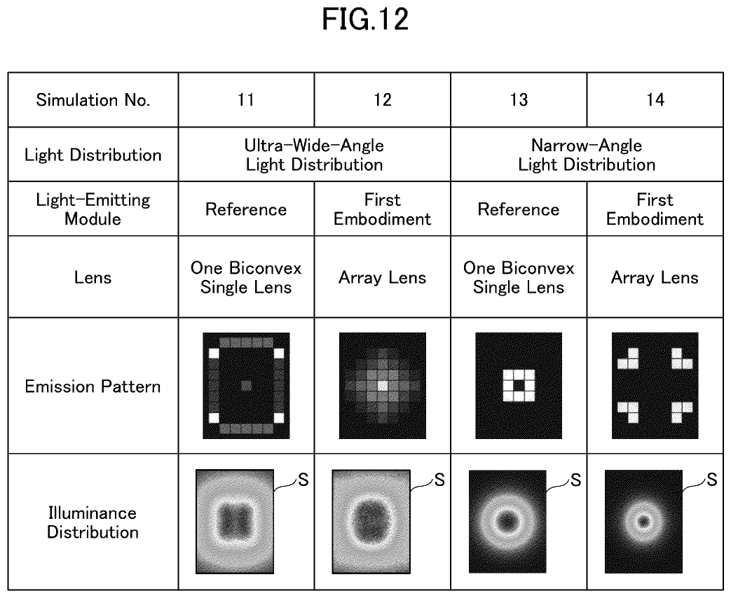

The simulation results of the relationship among the emission pattern, light distribution, and illuminance of the light source 1 will be described with reference to FIGS. 10 to 12. FIG. 10 is a first diagram showing an example of the relationship among the emission pattern, light distribution, and illuminance of the light source 1 of the light-emitting module 100. FIG. 11 is a second diagram showing an example of the relationship among the emission pattern, light distribution, and illuminance of the light source 1 of the light-emitting module 100. FIG. 12 is a diagram showing an example of the relationship between the emission pattern and illuminance in the ultra-wide-angle light distribution and the telephoto light distribution for each of the light-emitting module 100 and the light-emitting module according to a reference example. In the simulations shown in FIGS. 10 and 11, the light-emitting module 100 having the light source 1 with nine light-emitting parts 10 arranged in three rows and three columns was used. The curvature radius of the light-incident concave portion 24 was set to 0.15 mm, the curvature radius of the light-exiting concave portion was set to 0.10 mm, the maximum length M1 was set to 1.25 mm, and the maximum length M2 was set to 1.35 mm. In the simulation shown in FIG. 12, the light-emitting module 100 having the light source 1 with sixty-three light-emitting parts 10 arranged in nine rows and seven columns was used. The light-incident concave portion 24 and the light-exiting concave portion were not provided, the maximum length M1 was set to 1.25 mm, and the maximum length M2 was set to 1.35 mm.

The emission patterns shown in FIGS. 10 to 12 represent the emission patterns of the light source 1 viewed from the +Z side. In FIGS. 10 to 12, the emission intensity of the light-emitting part 10 is represented by the color of the light-emitting part 10 in the drawings. White, light gray, and dark gray indicate that the light-emitting part 10 is emitting light, and black indicates that the light-emitting part 10 is not emitting light. Among white, light gray, and dark gray, the lighter the color of the light-emitting part 10, the greater the emission intensity. Therefore, the emission intensity of the white light-emitting part 10 is the greatest.

In the graphs showing the light distribution in FIGS. 10 and 11, the vertical axis represents the relative luminous intensity (relative luminous intensity) with respect to the maximum luminous intensity. In FIGS. 10 and 11, the light distribution d1X represents the light distribution in the X direction passing through the center 1C of the light-emitting region 16 of the light source 1. The light distribution d1Y represents the light distribution in the Y direction passing through the center 1C of the light-emitting region 16 of the light source 1.

The illuminance distributions shown in FIGS. 10 to 12 represent the illuminance distributions on a rectangular irradiation surface S viewed from the −Z side. In FIG. 10, the closer the color in the drawing is to white, the higher the illuminance of the irradiation light, and the closer the color in the drawing is to black, the lower the illuminance of the irradiation light. In addition, when the entire circumference of a black area is surrounded by a white area, the black area has higher illuminance than the white area. The above described technique of viewing the illuminance distribution also applies to the illuminance distributions shown below.

As shown in simulation No. 1 in FIG. 10, when only the third light-emitting part 10-3 is caused to emit light, irradiation light with a wide-angle light distribution that illuminates the four corners of the irradiation surface S was obtained. As shown in simulation No. 2 in FIG. 10, when only one first light-emitting part 10-1 located on the +X side (second row, third column) is caused to emit light, irradiation light that illuminates both the +Y side and the −Y side in the central band in the X direction of the irradiation surface S was obtained. As shown in simulation No. 3 in FIG. 10, when only one first light-emitting part 10-1 located on the +Y side (first row, second column) is caused to emit light, irradiation light that illuminates both the +X side and the −X side in the central band in the Y direction of the irradiation surface S was obtained. As shown in simulation No. 4 in FIG. 10, when only one second light-emitting part 10-2 located at the corner portion 17 (first row, third column) is caused to emit light, irradiation light with a narrow-angle light distribution that illuminates the central area of the irradiation surface S was obtained.

In the light distribution of FIG. 10, as shown in the rows and columns for simulations No. 2 and No. 3, the luminous intensity values of light emitted from one first light-emitting part 10-1 and transmitted through the array lens 2 had two peaks. In contrast, as shown in simulation No. 4, the luminous intensity values of light emitted from one second light-emitting part 10-2 and transmitted through the array lens 2 had one peak. Thus, in the light-emitting module 100a, it was found that the light distribution is variable because the irradiation direction of light from the first light-emitting part 10-1 differs from that of light from the second light-emitting part 10-2. Therefore, in the second embodiment of the present disclosure, it is possible to provide the light-emitting module 100a suitable for variable light distribution.

Simulations No. 5 to No. 7 in FIG. 11 show the results when no diffusion plate for diffusing irradiation light from the light-emitting module 100 was disposed on the side of the array lens 2 opposite to the side where the light source 1 is located. Simulations No. 8 to No. 9 in FIG. 11 show the results when a diffusion plate was disposed.

In the simulation results without the diffusion plate, as shown in simulation No. 5 in FIG. 11, when all four second light-emitting parts 10-2 located at the four corner portions 17 were caused to emit light, irradiation light with a narrow-angle light distribution that illuminates the central area of the irradiation surface S was obtained. As shown in simulation No. 6 in FIG. 11, when the emission intensity of the third light-emitting part 10-3 was made the greatest, and the emission intensities of all the first light-emitting parts 10-1 and all the second light-emitting parts 10-2 were made substantially equal and less than that of the third light-emitting part 10-3, irradiation light with a wider light distribution than the narrow-angle light distribution obtained in simulation No. 5 was obtained. As shown in simulation No. 7 in FIG. 11, when the emission intensity of the third light-emitting part 10-3 was made the greatest, the emission intensities of all the first light-emitting parts 10-1 were made substantially equal and less than that of the third light-emitting part 10-3, and the emission intensities of all the second light-emitting parts 10-2 were made substantially equal and less than that of the first light-emitting parts 10-1, irradiation light with a wide-angle light distribution that illuminates the entire irradiation surface S was obtained.

In the simulation results with the diffusion plate, as shown in simulation No. 8 in FIG. 11, when all four second light-emitting parts 10-2 located at the four corner portions 17 were caused to emit light, irradiation light with a narrow-angle light distribution that illuminates the central area of the irradiation surface S was obtained. As shown in simulation No. 9 in FIG. 11, when the emission intensity of the third light-emitting part 10-3 was made the greatest, and the emission intensities of all the first light-emitting parts 10-1 and all the second light-emitting parts 10-2 were made substantially equal and less than that of the third light-emitting part 10-3, irradiation light with a wider light distribution than the narrow-angle light distribution obtained in simulation No. 8 was obtained. As shown in simulation No. 10 in FIG. 11, when the emission intensity of the third light-emitting part 10-3 was made the greatest, the emission intensities of all the first light-emitting parts 10-1 were made substantially equal and less than that of the third light-emitting part 10-3, and the emission intensities of all the second light-emitting parts 10-2 were substantially made equal and less than that of the first light-emitting parts 10-1, irradiation light with a wide-angle light distribution that illuminates the entire irradiation surface S was obtained. Compared to the simulation results without the diffusion plate, the simulation results with the diffusion plate showed overall uniformity in illuminance.

FIG. 12 shows simulation results when light with an ultra-wide-angle light distribution and light with a narrow-angle light distribution were respectively irradiated in each of the light-emitting module according to the reference example and the light-emitting module 100 according to the first embodiment. In FIG. 12, the light-emitting module according to the reference example and the light-emitting module 100 according to the first embodiment each had a light source 1 including sixty-three light-emitting parts 10 arranged in nine rows and seven columns. The light-emitting module according to the reference example differed from the light-emitting module 100 according to the first embodiment in that one biconvex single lens was disposed above the light source 1.

Simulations No. 11 to No. 14 in FIG. 12 show, in order, the ultra-wide-angle light distribution of the light-emitting module according to the reference example, the ultra-wide-angle light distribution of the light-emitting module 100 according to the first embodiment, the narrow-angle light distribution of the light-emitting module according to the reference example, and the narrow-angle light distribution of the light-emitting module 100 according to the first embodiment.

As shown in FIG. 12, in the light-emitting module 100 according to the first embodiment, compared to the light-emitting module according to the reference example, irradiation light with a wider light distribution was obtained in the ultra-wide-angle light distribution, and irradiation light with a narrower light distribution was obtained in the narrow-angle light distribution.

### Relationship Between Curvature Radius of Light-Incident Concave Portion 24 and Peripheral Illuminance and Central Illuminance

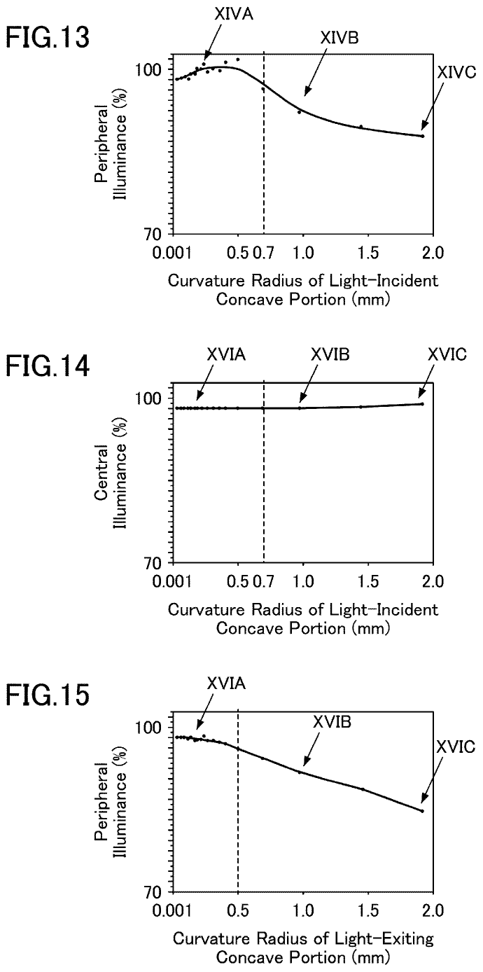

The light-incident concave portion 24 includes a curved surface in a cross section parallel to the Z-axis intersecting the connecting portion 21. The simulation results of the relationship between the curvature radius of the curved surface of the light-incident concave portion 24 and the peripheral illuminance and central illuminance will be described with reference to FIGS. 13 and 14.

FIG. 13 is a diagram showing an example of the relationship between the curvature radius of the light-incident concave portion 24 of the array lens 2 in the light-emitting module 100a and the peripheral illuminance. In this simulation, only the third light-emitting part 10-3 among the nine light-emitting parts 10 was caused to emit light. In FIG. 13, the peripheral illuminance at a curvature radius near XIVA, the peripheral illuminance at a curvature radius near XIVB, and the peripheral illuminance at a curvature radius near XIVC were compared. In this specification, “peripheral illuminance” refers to the illuminance at a position corresponding to an ultra-wide-angle horizontal angle of view of about 120° of a camera angle of view.

FIG. 14 is a diagram showing an example of the relationship between the curvature radius of the light-incident concave portion 24 of the array lens 2 in the light-emitting module 100a and the central illuminance. In this simulation, only the four second light-emitting parts 10-2 located at the four corner portions 17 among the nine light-emitting parts 10 were caused to emit light. In FIG. 15, the peripheral illuminance at a curvature radius near XIVA, the peripheral illuminance at a curvature radius near XIVB, and the peripheral illuminance at a curvature radius near XIVC were compared.

FIG. 13 shows changes in peripheral illuminance of irradiation light from the light-emitting module 100a when the curvature radius of the light-exiting concave portion 25 is fixed at 0.001 mm and the curvature radius of the light-incident concave portion 24 is varied from 0.001 mm to 2.0 mm. As shown in FIG. 13, the peripheral illuminance of irradiation light from the light-emitting module 100a was highest at the curvature radius near XIVA in FIG. 13, and decreased in order at the curvature radius near XIVB and the curvature radius near XIVC.

FIG. 14 shows changes in central illuminance of irradiation light from the light-emitting module 100a when the curvature radius of the light-exiting concave portion 25 is set to 0.001 mm and the curvature radius of the light-incident concave portion 24 is varied from 0.001 mm to 2.0 mm. As shown in FIG. 14, the central illuminance of irradiation light from the light-emitting module 100a was lowest at the curvature radius near XIVA in FIG. 15, and increased in order at the curvature radius near XIVB and the curvature radius near XIVC, but there was almost no difference in central illuminance.

The maximum length M1 of the light-incident surface 20a in the lens part 20 was set to 1.25 mm. As shown in FIGS. 13 and 14, when the curvature radius of the light-incident concave portion 24 was 0.005 mm or more and 0.7 mm or less, the peripheral illuminance was 95% or more of. Therefore, it was found that the ratio of the curvature radius of the curved surface of the light-incident concave portion 24 to the maximum length M1 is preferably 0.04 or more and 0.56 or less. Satisfying this condition can reduce diffusion or scattering of light at the light-incident concave portion 24 and increase the illuminance of light extracted from the array lens 2.

### Relationship Between Curvature Radius of Light-Exiting Concave Portion 25 and Peripheral Illuminance and Central Illuminance

The light-exiting concave portion 25 includes a curved surface in a cross section parallel to the Z-axis intersecting the connecting portion 21. The simulation results of the relationship between the curvature radius of the light-exiting concave portion 25 and the peripheral illuminance and central illuminance will be described with reference to FIGS. 15, 16A, 16B, 16C, 17, 18A, 18B, and 18C.

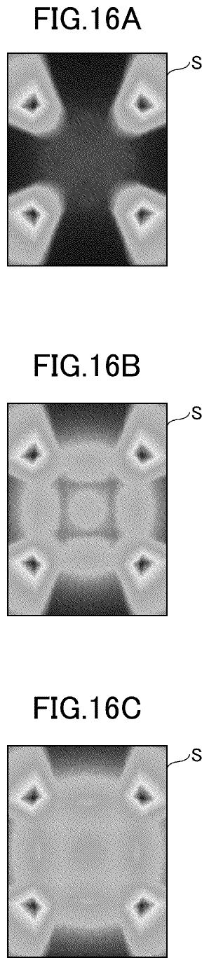

FIG. 15 is a diagram showing an example of the relationship between the curvature radius of the light-exiting concave portion 25 of the array lens 2 in the light-emitting module 100a and the peripheral illuminance. In this simulation, only the third light-emitting part 10-3 among the nine light-emitting parts 10 was caused to emit light. FIG. 16A is a diagram showing the illuminance distribution of irradiation light when the curvature radius of the light-exiting concave portion 25 is near XVIA in FIG. 15. FIG. 16B is a diagram showing the illuminance distribution of irradiation light when the curvature radius of the light-exiting concave portion 25 is near XVIB in FIG. 15. FIG. 16C is a diagram showing the illuminance distribution of irradiation light when the curvature radius of the light-exiting concave portion 25 is near XVIC in FIG. 15.

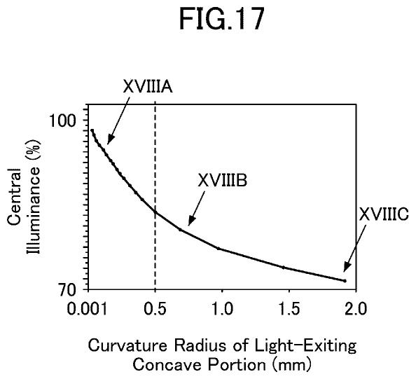

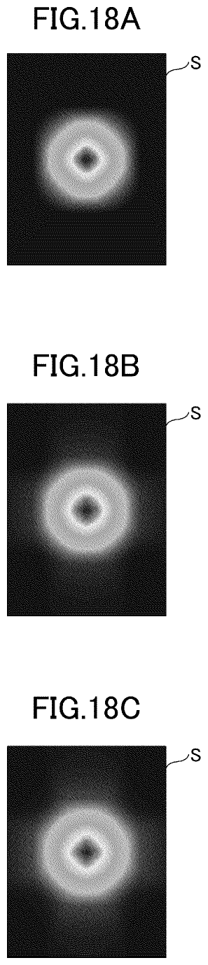

FIG. 17 is a diagram showing an example of the relationship between the curvature radius of the light-exiting concave portion 25 of the array lens 2 in the light-emitting module 100a and the central illuminance. In this simulation, only the four second light-emitting parts 10-2 located at the four corner portions 17 among the nine light-emitting parts 10 were caused to emit light. FIG. 18A is a diagram showing the illuminance distribution of irradiation light when the curvature radius of the light-exiting concave portion 25 is near XVIIIA in FIG. 17. FIG. 18B is a diagram showing the illuminance distribution of irradiation light when the curvature radius of the light-exiting concave portion 25 is near XVIIIB in FIG. 17. FIG. 18C is a diagram showing the illuminance distribution of irradiation light when the curvature radius of the light-exiting concave portion 25 is near XVIIIC in FIG. 17.

FIG. 15 shows changes in peripheral illuminance of irradiation light from the light-emitting module 100a when the curvature radius of the light-incident concave portion 24 is fixed at 0.001 mm and the curvature radius of the light-exiting concave portion 25 is varied from 0.001 mm to 2.0 mm. As shown in FIGS. 15, 16A, 16B, and 16C, the peripheral illuminance of irradiation light from the light-emitting module 100a was highest at the curvature radius near XVIA in FIG. 15, and decreased in order at the curvature radius near XVIB and the curvature radius near XVIC.

FIG. 17 shows changes in central illuminance of irradiation light from the light-emitting module 100a when the curvature radius of the light-incident concave portion 24 is fixed at 0.001 mm and the curvature radius of the light-exiting concave portion 25 is varied from 0.001 mm to 2.0 mm. As shown in FIGS. 17, 18A, 18B, and 18C, the central illuminance of irradiation light from the light-emitting module 100a was highest at the curvature radius near XVIIIA in FIG. 17, and decreased in order at the curvature radius near XVIIIB and the curvature radius near XVIIIC.

The maximum length M2 of the light-exiting surface 20b in the lens part 20 was set to 1.35 mm. As shown in FIGS. 15 and 17, when the curvature radius of the light-exiting concave portion 25 was 0.001 mm or more and 0.5 mm or less, the peripheral illuminance was 95% or more. Therefore, it was found that the ratio of the curvature radius of the curved surface of the light-exiting concave portion 25 to the maximum length M2 is preferably 0.0007 or more and 0.38 or less. Satisfying this condition can reduce diffusion or reflection of light at the light-exiting concave portion 25 and maintain the illuminance of light extracted from the array lens 2.

### MODIFIED EXAMPLES

Hereinafter, light-emitting modules according to the first to twelfth modified examples will be described. The light-emitting modules according to each modified example can be applied to each of the first embodiment and the second embodiment described above.

In each of the light-emitting modules according to the first to fourth modified examples, the light source 1 includes a plurality of second light-emitting parts 10-21 that emit light of different chromaticities, and the plurality of second light-emitting parts 10-21 are disposed below respectively different lens parts 20 among the plurality of lens parts 20. This differs from the light-emitting module 100 according to the first embodiment. The light source 1 in each of the first to fourth modified examples includes a plurality of second light-emitting parts 10-21 that emit light of different chromaticities, so that the light emitted from the light-emitting module can be color-adjusted.

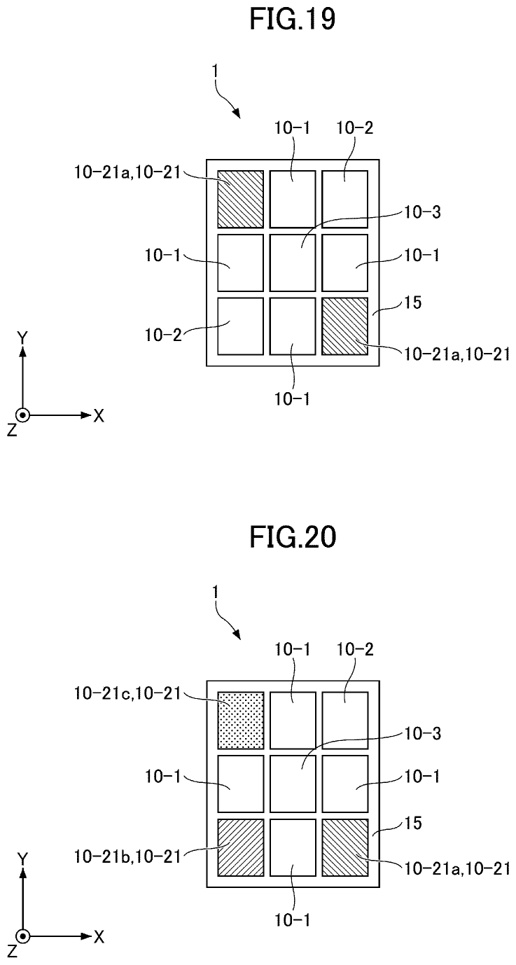

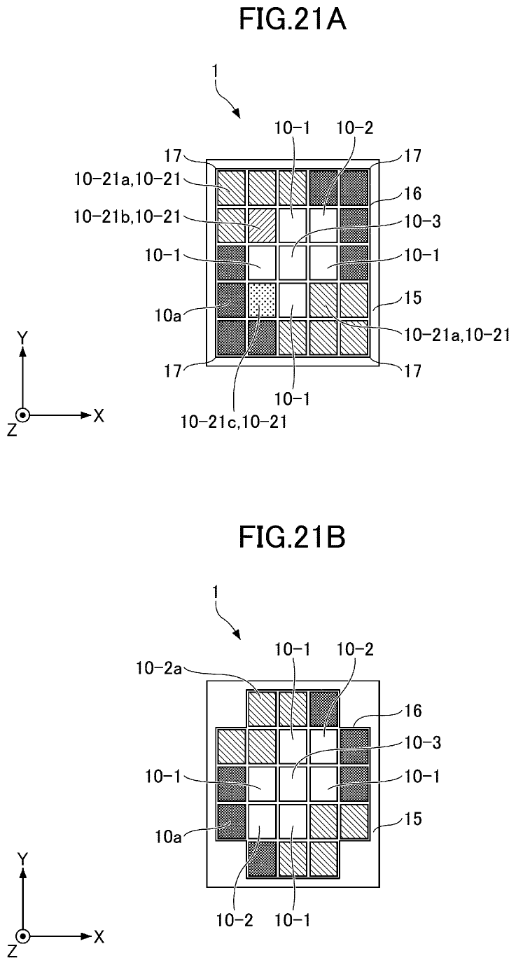

In FIGS. 19, 20, 21A, and 21B, the plurality of second light-emitting parts 10-21 include a second light-emitting part 10-21a indicated by a right-downward diagonal line pattern, a second light-emitting part 10-21b indicated by a left-downward diagonal line pattern, and a second light-emitting part 10-21c indicated by a wide-dot pattern. Second light-emitting parts 10-21 with the same pattern emit light of the same color, and second light-emitting parts 10-21 with different patterns emit light of different colors. For example, the second light-emitting part 10-21a indicated by the right-downward diagonal line pattern emits red light. The second light-emitting part 10-21b indicated by the left-downward diagonal line pattern emits blue light. The second light-emitting part 10-21c indicated by the wide-dot pattern emits green light. In addition, the light-emitting part 10a indicated by the narrow-dot pattern in FIGS. 21A and 21B represents that the chromaticity of the emitted light can be changed as appropriate.

### First Modified Example

FIG. 19 is a schematic top view of the light source 1 of the light-emitting module according to the first modified example. In the light-emitting module according to the first modified example, the second light-emitting parts 10-21a that emit red light are disposed at two diagonally opposite corner portions 17 among the four corner portions 17. The number of light-emitting parts 10 may be ten or more.

### Second Modified Example

FIG. 20 is a schematic top view of the light source 1 of the light-emitting module according to the second modified example. In the light-emitting module according to the second modified example, the second light-emitting part 10-21a that emits red light, the second light-emitting part 10-21b that emits blue light, and the second light-emitting part 10-21c that emits green light are respectively disposed at three of the four corner portions 17. The number of light-emitting parts 10 may be ten or more.

### Third Modified Example

FIG. 21A is a schematic top view showing a first example of the light source 1 of the light-emitting module according to the third modified example. In the first example of the third modified example, the second light-emitting parts 10-21a that emit red light are disposed along the outer edge of the light-emitting region 16 near two diagonally opposite corner portions 17 among the four corner portions 17, with a total of eight second light-emitting parts 10-21a. In addition, the second light-emitting part 10-21a is disposed between one light-emitting part 10 located at a corner portion 17 and the third light-emitting part 10-3. The second light-emitting part 10-21b is disposed between one light-emitting part 10 located at a corner portion 17 and the third light-emitting part 10-3. The second light-emitting part 10-21c is disposed between one light-emitting part 10 located at a corner portion 17 and the third light-emitting part 10-3. In this way, a plurality of second light-emitting parts 10-21 (or a plurality of light-emitting parts 10a) can be disposed near two diagonally opposite corner portions 17 among the four corner portions 17. In this case, the plurality of second light-emitting parts 10-21 (or the plurality of light-emitting parts 10a) can be regarded as one group. A group of second light-emitting parts 10-21 emitting light of different chromaticities, (for example, a group of second light-emitting parts 10-21a, a group of second light-emitting parts 10-21b, a group of second light-emitting parts 10-21c, or a group of light-emitting parts 10a) may be disposed at each of the four corner portions 17.

FIG. 21B is a schematic top view showing a second example of the light source 1 of the light-emitting module according to the third modified example. In the second example of the third modified example, the light-emitting region 16 is not rectangular, and the second light-emitting parts 10-2a that emit red light are disposed near the outer edge of the light-emitting region 16, with a total of eight second light-emitting parts 10-21a. When the light-emitting region 16 is not rectangular, the plurality of second light-emitting parts 10-21 can be disposed near the outer edge of the light-emitting region 16 along the outer edge of the light-emitting region 16.

### Fourth Modified Example

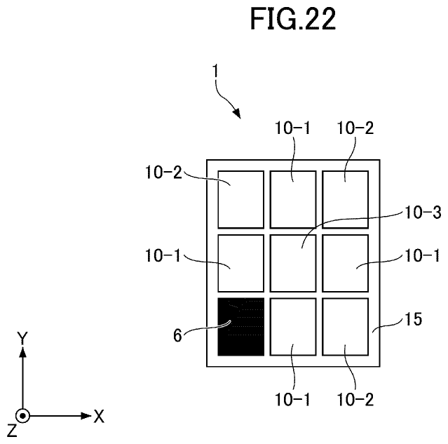

FIG. 22 is a schematic top view showing the light source 1 of the light-emitting module according to the fourth modified example. In the light-emitting module according to the fourth modified example, an electronic component 6 is disposed at one of the four corner portions 17, which differs from the light-emitting module 100 according to the first embodiment. Examples of the electronic component 6 include a Zener diode, a thermistor, a capacitor, a light-receiving sensor, or a combination thereof. Example of the electronic component 6 shown in FIG. 22 includes a light-receiving sensor that detects the amount of light entering the inside of the light-emitting module from the outside of the light-emitting module through the array lens 2. When the electronic component 6 is a light-receiving sensor, a convex lens is located directly above the electronic component 6, allowing light to be received in a focused state, thereby improving the light-receiving efficiency of the light-receiving sensor.

### Fifth Modified Example

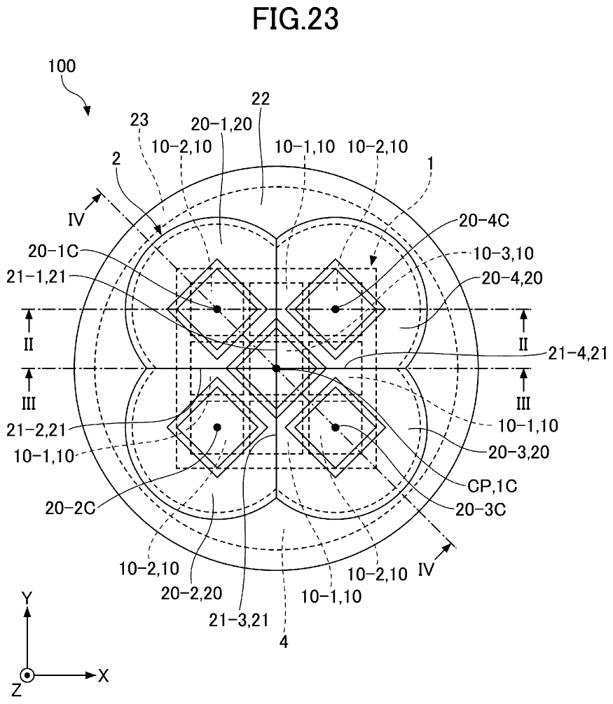

FIG. 23 is a schematic top view showing the light source 1 of the light-emitting module according to the fifth modified example. In the light-emitting module according to the fifth modified example, all the light-emitting parts 10 are rotated 45 degrees around a rotation center defined by a line passing through the center 1C of the light-emitting region 16 and parallel to the normal of the light-emitting surface 11, and adjacent light-emitting parts 10 are disposed apart from each other. This differs from the light-emitting module 100 according to the first embodiment. In this modified example, in a top view, the third light-emitting part 10-3 overlaps the connecting portion 21 (intersection CP). In addition, the second light-emitting part 10-2 is disposed below one of the lens parts 20 and does not overlap the connecting portion 21. In this modified example, the light-emitting parts 10 do not have to be disposed below the linearly extending connecting portions 21-1, 21-2, 21-3, and 21-4. This can allow the size of each light-emitting part 10 in a top view to be increased.

### Sixth Modified Example

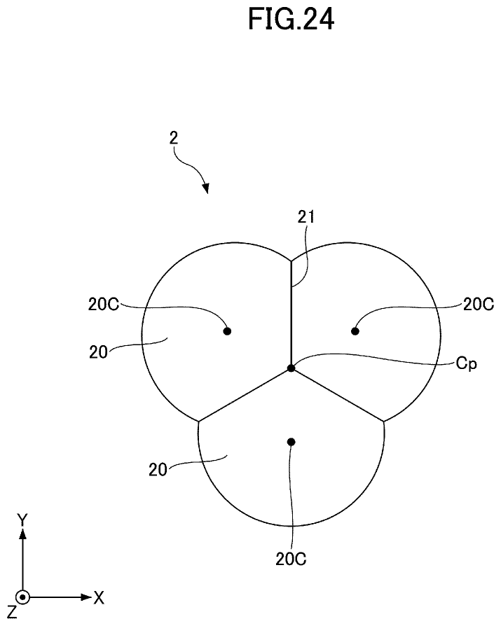

FIG. 24 is a schematic top view of the array lens 2 of the light-emitting module according to the sixth modified example. In the light-emitting module according to the sixth modified example, each of the plurality of lens parts 20 has an optical axis 20C, and the optical axes 20C of the plurality of lens parts 20 are arranged at vertices of a triangular shape in a top view, which differs from the light-emitting module 100 according to the first embodiment.

In the example shown in FIG. 24, each of the three lens parts 20 has an optical axis 20C. The optical axes 20C of the three lens parts 20 are arranged at vertices of the triangular shape in a top view. The light-emitting module according to the sixth modified example can also achieve the same or similar effects as those described in the first embodiment.

### Seventh Modified Example

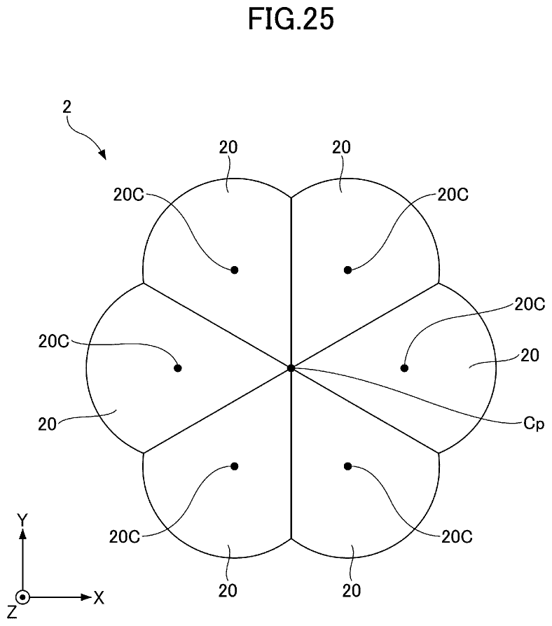

FIG. 25 is a schematic top view of the array lens 2 of the light-emitting module according to the seventh modified example. In the light-emitting module according to the seventh modified example, each of the plurality of lens parts 20 has an optical axis 20C. The optical axes 20C of the plurality of lens parts 20 are arranged at vertices of a honeycomb shape in a top view, which differs from the light-emitting module 100 according to the first embodiment.

In the example shown in FIG. 25, each of the six lens parts 20 has an optical axis 20C, and the optical axes 20C of the six lens parts 20 are arranged at vertices of the honeycomb shape in a top view. The light-emitting module according to the seventh modified example can also achieve the same or similar effects as those described in the first embodiment.

### Eighth Modified Example

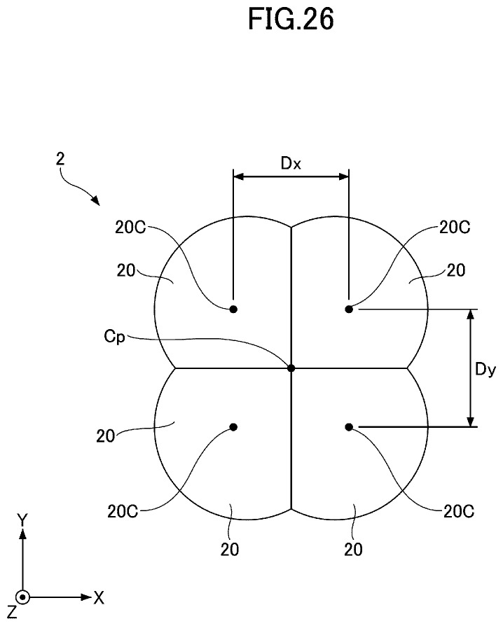

FIG. 26 is a schematic top view of the array lens 2 of the light-emitting module according to the eighth modified example. In the light-emitting module according to the eighth modified example, the array lens 2 includes four or more lens parts 20. Each of the four or more lens parts 20 has an optical axis 20C. In a top view, the optical axes 20C are arranged in a matrix. In a top view, the distance Dx between two optical axes 20C adjacent along a first direction is different from the distance Dy between two optical axes 20C adjacent along a second direction, which differs from the light-emitting module 100 according to the first embodiment.

In the example shown in FIG. 26, the X direction corresponds to the first direction, and the Y direction corresponds to the second direction orthogonal to the first direction. The array lens 2 includes four lens parts 20. Each of the four lens parts 20 has an optical axis 20C. In a top view, the distance Dx between two optical axes 20C adjacent along the X direction is shorter than the distance Dy between two optical axes 20C adjacent along the Y direction. That is, in a top view, the lines connecting the four optical axes 20C form a rectangular shape.

In the light-emitting module according to the eighth modified example, the illuminance of irradiation light to a rectangular irradiation area corresponding to a camera angle of view can be made uniform. The effects of the light-emitting module according to the eighth modified example other than those described above are the same as or similar to those described in the first embodiment.

### Ninth Modified Example

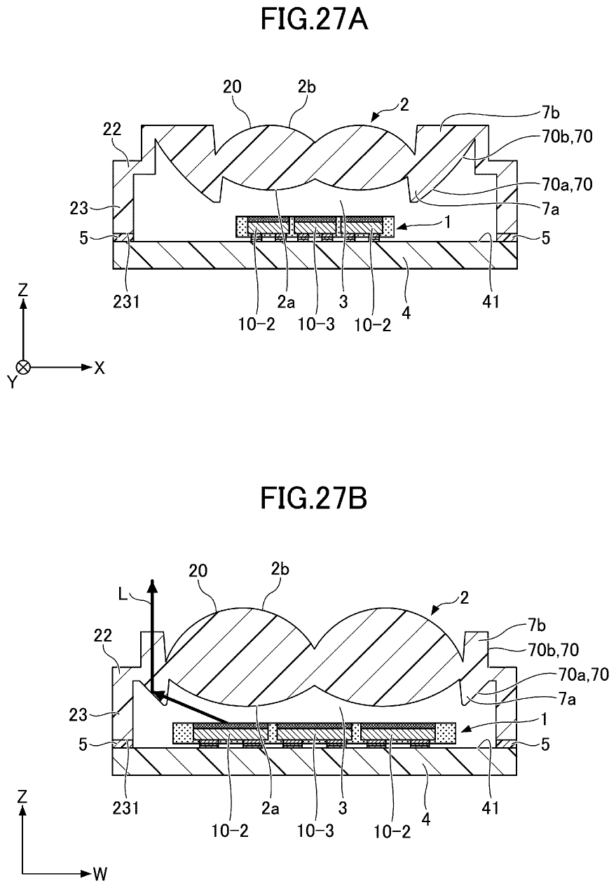

FIGS. 27A and 27B are schematic cross-sectional views of the light-emitting module according to the ninth modified example. FIG. 27A shows a cross section of the light-emitting module according to the ninth modified example corresponding to line III-III in FIG. 1. FIG. 27B shows a cross section of the light-emitting module according to the ninth modified example corresponding to line IV-IV in FIG. 1.

In the light-emitting module according to the ninth modified example, the array lens 2 includes a light-incident surface 2a that is a surface closer to the light source 1, and a convex portion 7a provided on the light-incident surface 2a and surrounding the plurality of lens parts 20 so as to be convex toward the side where the light source 1 is located. The convex portion 7a has a light-reflecting surface 70a. These points differ from the light-emitting module 100 according to the first embodiment.

In the example shown in FIGS. 27A and 27B, the array lens 2 further includes a convex portion 7b provided on the light-exiting surface 2b and surrounding the plurality of lens parts 20 so as to be convex toward the side opposite to the side where the light source 1 is located. The convex portion 7b has a light-reflecting surface 70b. The light-reflecting surface 70a of the convex portion 7a and the light-reflecting surface 70b of the convex portion 7b are connected to each other to form a light-reflecting surface 70. The upper surface of the convex portion 7b is a flat surface. Light L emitted from the −X side end of the light source 1 enters the convex portion 7a, passes through the convex portion 7a, and is totally reflected by the light-reflecting surface 70. The light L totally reflected by the light-reflecting surface 70 passes through the convex portion 7b and is irradiated toward the +Z side. The array lens 2 does not have to have the convex portion 7b. The upper surface of the convex portion 7b is not limited to a flat surface and does not have to be a rough surface.

In the light-emitting module according to the ninth modified example, the light-reflecting surface 70 reflects light L that has been emitted from the light source 1 and is directed toward the support portion 22 and the leg portion 23, so that stray light can be reduced. The effects of the light-emitting module according to the ninth modified example other than those described above are the same as or similar to those described in the first embodiment.

### Tenth Modified Example

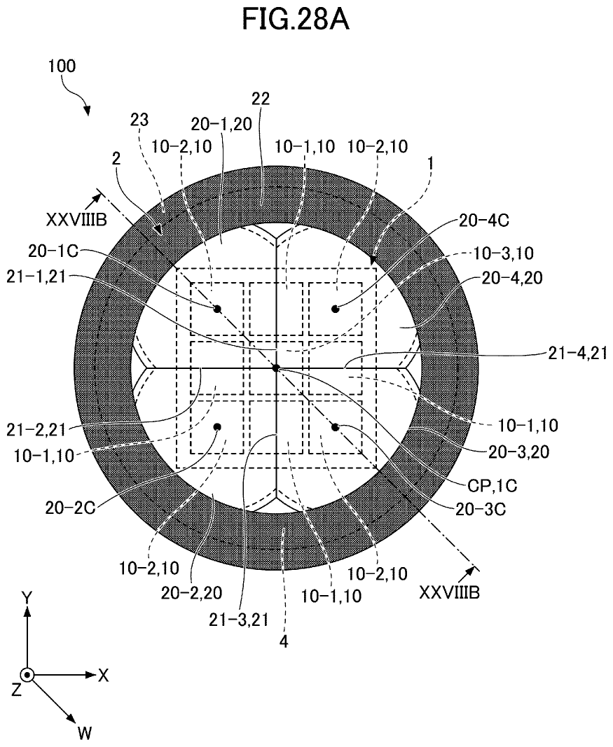

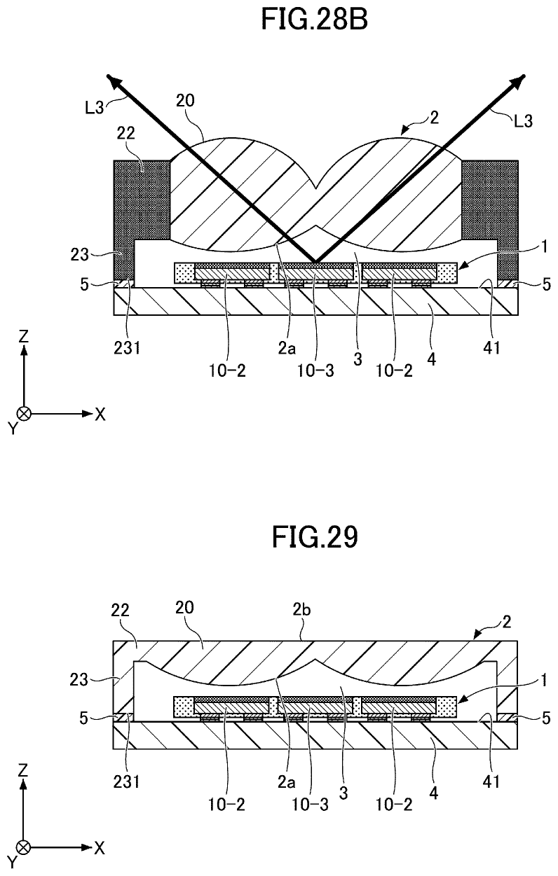

FIG. 28A is a schematic top view of the light-emitting module according to the tenth modified example.

FIG. 28B is a schematic cross-sectional view taken along line XXVIIIB-XXVIIIB in FIG. 28A.

In the light-emitting module according to the tenth modified example, the support portion 22 and the leg portion 23 of the array lens 2 each have light-shielding properties, which differs from the light-emitting module 100 according to the first embodiment.

In the light-emitting module according to the tenth modified example, the support portion 22 and the leg portion 23 are light absorptive and dark in color. In the example shown in FIG. 28A, the support portion 22 and the leg portion 23 are formed of a metal material and have a black coating on the surface. However, the support portion 22 and the leg portion 23 may be formed of, for example, a resin material and have a black coating on the surface. The support portion 22 and the leg portion 23 may also be members containing carbon black and a resin material. When the support portion 22 and the leg portion 23 are light absorptive, stray light can be reduced and the contrast of irradiation light on the irradiation surface can be increased. The support portion 22 and the leg portion 23 may also be light reflective and members containing a resin material and a light-reflective material such as white pigment, similar to the covering member 15 described above. When the support portion 22 and the leg portion 23 are light reflective, the amount of light incident on the lens part 20 increases, improving light extraction efficiency. That is, in this modified example, “light-shielding properties” include both light absorptivity and light reflectivity.

In the light-emitting module according to the tenth modified example, as shown in FIG. 28B, light L emitted from at least one of the first light-emitting part 10-1 or the third light-emitting part 10-3 disposed at a position overlapping the connecting portion 21 in a top view (principal ray L3 is shown in FIG. 28B) becomes wide-angle light distribution. Because the region outward of the array lens 2 hardly affects the wide-angle light distribution, in the light-emitting module according to this modified example, the support portion 22 and the leg portion 23 of the array lens 2 each have light-shielding properties, and the light-transmissive region of the array lens 2 in a top view can be reduced. This can reduce the visibility of the inside of the light-emitting module, so that the aesthetic appearance of the light-emitting module can be improved. Reducing the light-transmissive region of the array lens 2 in a top view reduces the area of the light-incident surface 20a and the light-exiting surface 20b of each lens part 20 (that is, the area for controlling light of the lens part 20), but in this modified example, because the four second light-emitting parts 10-2 are symmetrically arranged around the intersection CP, by causing the four second light-emitting parts 10-2 to emit light simultaneously, unevenness in the illuminance distribution of the irradiation light can be reduced. The effects of the light-emitting module according to the tenth modified example other than those described above are the same as or similar to those described in the first embodiment.

### Eleventh Modified Example

FIG. 29 is a schematic cross-sectional view of the light-emitting module according to the eleventh modified example.

FIG. 29 shows a cross section of the light-emitting module according to the eleventh modified example corresponding to line IV-IV in FIG. 1.

In the light-emitting module according to the eleventh modified example, the light-exiting surface 2b of the array lens 2 is flat, which differs from the light-emitting module 100 according to the first embodiment. In the example shown in FIG. 29, the light-exiting surface 2b of the array lens 2 is a surface parallel to the light-emitting surface 11 of the light-emitting part 10.

In the light-emitting module according to the eleventh modified example, because the light-exiting surface 2b of the array lens 2 is flat, that is, the light-exiting surface 20b of the lens part 20 is flat, the light-exiting surface 2b of the lens part 20 can be less likely to be damaged compared to when the light-exiting surface 2b is convex. The effects of the light-emitting module according to the eleventh modified example other than those described above are the same as or similar to those described in the first embodiment.

### Twelfth Modified Example

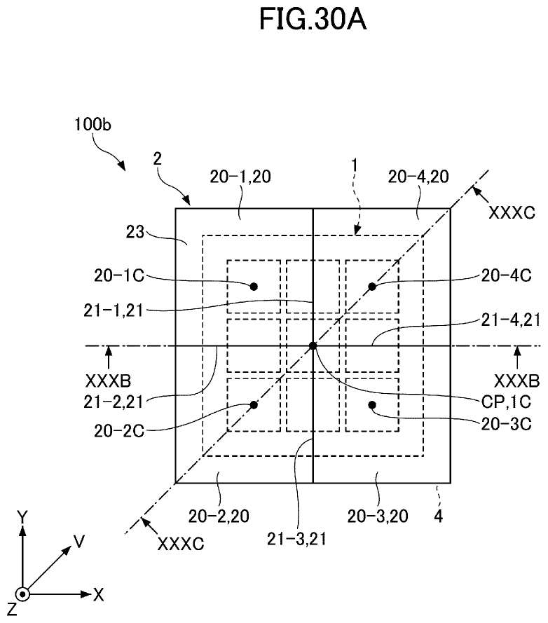

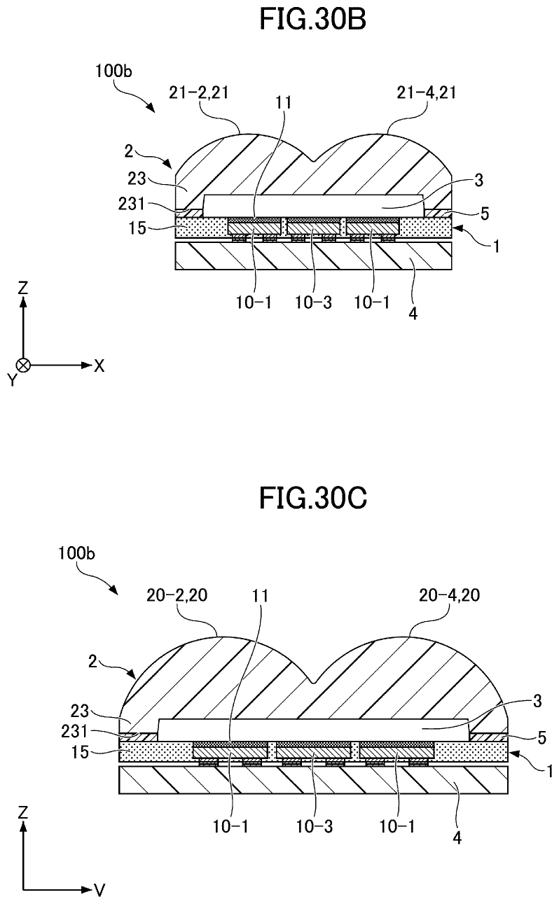

The light-emitting module according to the twelfth modified example will be described with reference to FIGS. 30A, 30B, and 30C.

FIG. 30A is a schematic top view of the light-emitting module 100b according to the twelfth modified example.

FIG. 30B is a schematic cross-sectional view taken along line XXXB-XXXB in FIG. 30A.

FIG. 30C is a schematic cross-sectional view taken along line XXXC-XXXC in FIG. 30A.

As shown in FIG. 30A, the light-emitting module 100b has a rectangular outer edge shape in a top view, the light-incident surface 20a of the lens part 20 is flat, and the leg portion 23 and the covering member 15 are bonded together, which mainly differs from the light-emitting module 100 according to the first embodiment.

In the example shown in FIG. 30A, the outer edge shape of the array lens 2 of the light-emitting module 100b is rectangular in a top view. The outer edge shape of the wiring substrate 4 in the light-emitting module 100b is rectangular in a top view. In a top view, the outer edge of the array lens 2 and the outer edge of the wiring substrate 4 overlap to each other. The outer edge of the light-emitting module 100b is both the outer edge of the array lens 2 and the outer edge of the wiring substrate 4.

In the examples shown in FIGS. 30B and 30C, the adhesive member 5 is disposed between the lower surface 231 of the leg portion 23 of the array lens 2 and the upper surface of the covering member 15, joining the array lens 2 and the covering member 15. This can allow the light-emitting module 100b to have a space 3 between the light-emitting surface 11 of the light source 1 and the array lens 2. The array lens 2 only needs to be spaced apart from the light-emitting surface 11 via the space 3. In this modified example, because heat is easily transferred to the array lens 2 when the light-emitting module 100b is joined to a mounting substrate by soldering or the like, the array lens 2 is preferably formed of a resin material with high heat resistance, such as silicone resin. In addition, when the light-emitting module 100b is joined to a mounting substrate by soldering or the like, the air in the space 3 expands, thus an opening for releasing the air to the outside may be provided in the leg portion 23 of the array lens 2.

The light-emitting module 100b can also achieve the effects same as or similar to that of the light-emitting module 100 according to the first embodiment.

### Thirteenth Modified Example

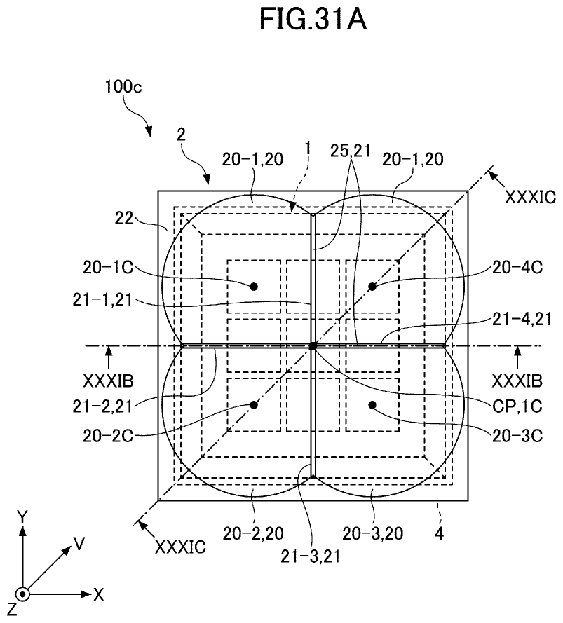

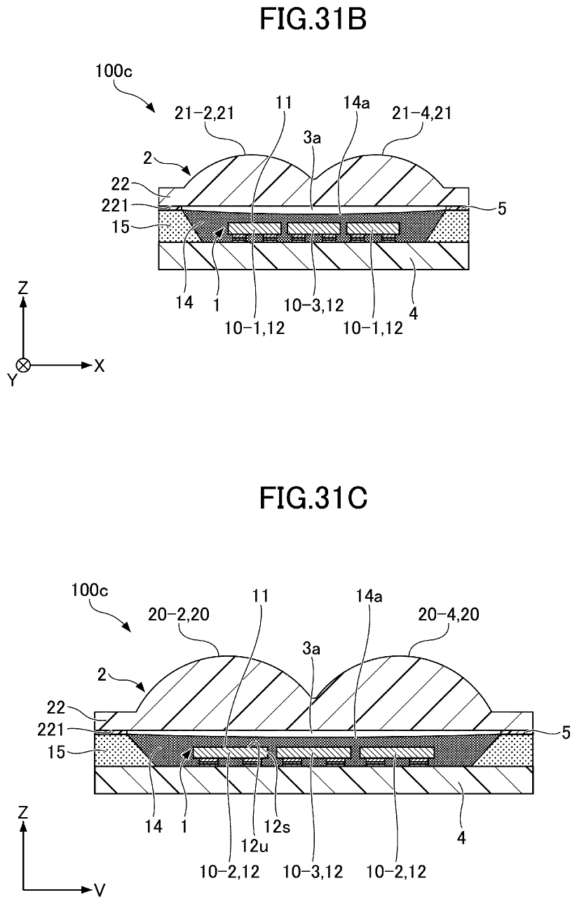

The light-emitting module according to the thirteenth modified example will be described with reference to FIGS. 31A, 31B, and 31C.

FIG. 31A is a schematic top view of the light-emitting module 100c according to the thirteenth modified example.

FIG. 31B is a schematic cross-sectional view taken along line XXXIB-XXXIB in FIG. 31A.

FIG. 31C is a schematic cross-sectional view taken along line XXXIC-XXXIC in FIG. 31A.

As shown in FIGS. 31B and 31C, the light-emitting module 100c has a flat light-incident surface 20a of the lens part 20, and the support portion 22 and the covering member 15 are joined together. In addition, the wavelength conversion member 14 covers the lateral surfaces 12s of the plurality of light-emitting elements 12, and the covering member 15 covers the lateral surfaces 12s of the plurality of light-emitting elements 12 via the wavelength conversion member 14. These points mainly differ from the light-emitting module 100 according to the first embodiment. In this modified example, the light source 1 is the light-emitting element 12, and the light-emitting surface 11 of the light source 1 is the upper surface 12u of the light-emitting element 12.

In the examples shown in FIGS. 31B and 31C, the adhesive member 5 is disposed between the lower surface 221 of the support portion 22 of the array lens 2 and the upper surface of the covering member 15, joining the array lens 2 and the covering member 15. The wavelength conversion member 14 covers the upper surfaces 12u and the lateral surfaces 12s of the plurality of light-emitting elements 12. In this modified example, the upper surface of the wavelength conversion member 14 has a concave surface 14a. The concave surface 14a is a recess formed on the upper surface of the wavelength conversion member 14 due to shrinkage occurring when the resin material contained in the wavelength conversion member 14 solidifies during the manufacturing process of covering the plurality of light-emitting elements 12 with the wavelength conversion member 14. In the light-emitting module 100c, the concave surface 14a and the array lens 2 are spaced apart, thereby providing a space 3a. In this modified example, the array lens 2 is disposed above the light source 1 (light-emitting element 12) with the space 3a therebetween.

The light-emitting module 100c can also achieve the effects same as or similar to the light-emitting module 100 according to the first embodiment.

While preferred embodiments have been described in detail above, the embodiments described above are not limiting, and various modifications and substitutions can be made to the embodiments described above without departing from the scope described in the claims.

The ordinal numbers, quantities, and other numerical values used in the description of the embodiments are all illustrative for specifically explaining the technology of the present disclosure, and the present disclosure is not limited to the illustrated numerical values. In addition, the connection relationships between components are illustrative for specifically explaining the technology of the present disclosure, and are not limited to the connection relationships for realizing the functions of the present disclosure.

Because the light-emitting module of the present disclosure is capable of light distribution control, it can be suitably used for lighting, camera flashes, vehicle headlights, and the like. However, the light-emitting module of the present disclosure is not limited to these applications.

What is claimed is:

1. A light-emitting module comprising:
a light source comprising a plurality of light-emitting parts capable of individual operation or group operation, the plurality of light-emitting parts including at least one first light-emitting part and at least one second light-emitting part; and
an array lens comprising a plurality of lens parts having positive refractive power, the plurality of lens parts being connected by one or more connecting portions; wherein:
the array lens is disposed above the light source with a space therebetween; and
in a top view:
the at least one first light-emitting part overlaps the connecting portion, and
the at least one second light-emitting part is disposed below one of the lens parts and does not overlap the connecting portion.

2. The light-emitting module according to claim 1, wherein:
the one or more connecting portions comprise a plurality of the connecting portions each extending linearly in the top view;
the light source further includes a third light-emitting part; and
the third light-emitting part overlaps an intersection at which the plurality of connecting portions intersect in the top view.

3. The light-emitting module according to claim 2, wherein:
the array lens includes four of the lens parts and four of the connecting portions, and
the plurality of light-emitting parts include nine light-emitting parts arranged in a matrix in the top view, the nine-light-emitting parts including four of the first light-emitting parts respectively overlap the four connecting portions, and four of the second light-emitting parts are respectively disposed below the four lens parts, and do not overlap any of the four connecting portions.

4. The light-emitting module according to claim 1, wherein in the top view, a shape of an outer edge of a structure composed of the lens parts is an annular shape in which a plurality of arcs are connected.

5. The light-emitting module according to claim 1, wherein:
each of the lens parts has an optical axis; and
optical axes of the lens parts are arranged at vertices of a rectangular shape in the top view.

6. The light-emitting module according to claim 1, wherein:
each of the lens parts has an optical axis; and
the optical axes of the lens parts are arranged at vertices of a honeycomb shape or vertices of a triangular shape in the top view.

7. The light-emitting module according to claim 1, wherein:
the array lens includes a light-incident surface that is a surface closer to the light source, and comprises a convex portion provided on the light-incident surface and surrounding the lens parts so as to be convex toward a side where the light source is located, the convex portion having a light-reflecting surface.

8. The light-emitting module according to claim 1, wherein:
the array lens includes a light-incident surface that is a surface closer to the light source, and a light-exiting surface located on a side opposite to the light-incident surface;
at least one of the lens parts includes the light-incident surface as a convex surface; and
at least one of the one or more connecting portions includes a light-incident concave portion on the light-incident surface.

9. The light-emitting module according to claim 1, wherein:
the array lens includes a light-incident surface that is a surface closer to the light source, and a light-exiting surface located on a side opposite to the light-incident surface;
at least one of the lens parts includes the light-exiting surface as a convex surface; and
at least one of the connecting portions includes a light-exiting concave portion on the light-exiting surface.

10. The light-emitting module according to claim 1, wherein:
the array lens includes a light-incident surface that is a surface closer to the light source, and a light-exiting surface located on a side opposite to the light-incident surface;
at least one of the lens parts includes the light-incident surface as a convex surface and the light-exiting surface as a convex surface; and
at least one of the connecting portions includes a light-incident concave portion on the light-incident surface and a light-exiting concave portion on the light-exiting surface.

11. The light-emitting module according to claim 8, wherein:
each of the lens parts has an optical axis;
the light-incident concave portion includes a curved surface in a cross section intersecting one of the connecting portions; and
a ratio of a curvature radius of the curved surface to a maximum length from the optical axis of one of the lens parts to an outer edge of the light-incident surface of the one of the lens parts is 0.04 or more and 0.56 or less.

12. The light-emitting module according to claim 9, wherein:
each of the lens parts has an optical axis;
the light-exiting concave portion includes a curved surface in a cross section intersecting one of the connecting portions; and
a ratio of a curvature radius of the curved surface to a maximum length from the optical axis of one of the lens parts to an outer edge of the light-exiting surface of one of the lens parts is 0.0007 or more and 0.38 or less.

13. The light-emitting module according to claim 8, wherein a maximum width of the light-incident concave portion in a direction orthogonal to a direction in which one of the connecting portions extends is 0.001 mm or more and 0.5 mm or less.

14. The light-emitting module according to claim 9, wherein a maximum width of the light-exiting concave portion in a direction orthogonal to a direction in which one of the connecting portions extends is 0.001 mm or more and 0.5 mm or less.

15. The light-emitting module according to claim 10, wherein in the top view, an area of the light-incident concave portion is larger than an area of the light-exiting concave portion.

16. The light-emitting module according to claim 1, wherein:
the array lens includes four or more of the lens parts;
each of the four or more lens parts has an optical axis, the optical axes are arranged in a matrix in the top view; and
in the top view, a distance between two of the optical axes adjacent along a first direction is different from a distance between two of the optical axes adjacent along a second direction perpendicular to the first direction.

17. The light-emitting module according to claim 1, wherein:
light emitted from the at least one first light-emitting part and transmitted through the array lens has two peaks in luminous intensity values; and
light emitted from the at least one second light-emitting part and transmitted through the array lens has one peak in luminous intensity values.

18. The light-emitting module according to claim 1, wherein:
the light source includes a plurality of the second light-emitting parts that emit light of different chromaticities; and
the plurality of second light-emitting parts are disposed below respectively different lens parts among the plurality of lens parts.

19. The light-emitting module according to claim 1, wherein:
the light source includes a covering member; and
the plurality of light-emitting parts are connected to each other by the covering member.

20. A camera flash comprising the light-emitting module according to claim 1.
